(19) United States
(12) Patent Application Publication
(10) Pub. No.: US 2012/0119278 A1
(43) Pub. Date: May 17, 2012

(54) SEMICONDUCTOR DEVICE AND METHOD OF FORMING THE SAME

(75) Inventor: Noriaki MIKASA, Tokyo (JP)

(73) Assignee: ELPIDA MEMORY, INC., Tokyo (JP)

(21) Appl. No.: 13/296,440

(22) Filed: Nov. 15, 2011

(30) Foreign Application Priority Data
Nov. 16, 2010 (JP) 2010-256196

(51) Int. Cl. H01L 27/108; H01L 29/78

(52) U.S. Cl. 257/306; 257/330; 257/331; 257/E29.264; 257/E29.255; 257/E27.091

(57) ABSTRACT

A semiconductor device includes a semiconductor substrate and a first gate structure. The semiconductor substrate has a first groove and a first pillar defined by the first groove. The first groove and the first pillar are adjacent to each other. The first gate structure is disposed in the first groove. The first gate structure includes a first gate insulating film and a first gate electrode. The first gate structure is separated by a first gap from the first pillar.

### BACKGROUND OF THE INVENTION

1. Field of the Invention

The present invention generally relates to a semiconductor device and a method of forming the same.

Priority is claimed on Japanese Patent Application No. 2010-256196, filed Nov. 16, 2010, the content of which is incorporated herein by reference.

2. Description of the Related Art

In recent years, semiconductor devices such as DRAMs (Dynamic Random Access Memories) have been miniaturized. Thus, the transistors of the semiconductor devices are also miniaturized, thereby causing a problem of a short channel effect in the transistors.

In order to prevent this problem, the configuration of a vertical transistor (also referred to as a “three-dimensional transistor”) has been suggested in which a silicon pillar extending vertically with respect to a main surface of a semiconductor substrate is used as a channel (for example, JP-A-2010-219386).

JP-A-2010-219386 discloses a semiconductor device that includes silicon pillars formed on a semiconductor substrate, a first gate electrode formed in a first side surface of each silicon pillar with a gate insulation film interposed therebetween, a second gate electrode formed on a second side surface of each silicon pillar located opposite to the first side surface with a gate insulation film interposed therebetween, pairs of impurity diffusion regions, and bit lines perpendicular to the first and second gate electrodes.

JP-A-2010-219386 discloses a method of forming the gate insulation film in the silicon pillars, forming a conductive film serving as a base material of the first and second gate electrodes between the silicon pillars, and forming the first and second gate electrodes separate from each other by etching back the conductive film by dry etching.

However, when the semiconductor device is further miniaturized, the gap between the silicon pillars is narrowed, thereby increasing the aspect ratio of a groove formed between the silicon pillars.

Therefore, since an unnecessary conductive film located between the silicon pillars is rarely removed by the etching-back, it is difficult to form the first and second gate electrodes on the entire surface of the semiconductor substrate.

It may be considered that the first and second gate electrodes are formed on the entire surface of the semiconductor substrate by further etching back the conductive film to some extent. In this case, however, since the thicknesses (thickness in a direction perpendicular to the side surface of the pillar) of the first and second gate electrodes is less than a desired thickness, the resistance values of the first and second gate electrodes may increase.

Further, when the first and second gate electrodes are formed in the silicon pillar, a problem may arise in that the capacitance between the first and second gate electrodes increases.

### SUMMARY

In one embodiment, a semiconductor device may include, but is not limited to, a semiconductor substrate and a first gate structure. The semiconductor substrate has a first groove and a first pillar defined by the first groove. The first groove and the first pillar are adjacent to each other. The first gate structure is disposed in the first groove. The first gate structure includes a first gate insulating film and a first gate electrode. The first gate structure is separated by a first gap from the first pillar.

In another embodiment, a semiconductor device may include, but is not limited to, a semiconductor substrate and a first gate structure. The semiconductor substrate has a first groove and a first pillar defined by the first groove. The first groove and the first pillar are adjacent to each other. The first gate structure is disposed in the first groove. The first gate structure includes a first gate insulating film and a first gate electrode. The first gate structure is separated by a first empty space from the first pillar.

In another embodiment, a semiconductor device may include, but is not limited to, a semiconductor substrate, a first gate structure, a first insulating film, and a buried insulating film. The semiconductor substrate has first and second grooves extending in a first direction, and third and fourth grooves extending in a second direction crossing the first direction, and a first pillar defined by the first, second, third and fourth grooves. The first gate structure is disposed in a lower portion of the first groove. The first gate structure includes a first gate insulating film and a first gate electrode. The first insulating film is disposed in the first groove. The first insulating film covers a first side surface of the first pillar. The first side surface of the first pillar faces toward the gate structure. The first insulating film is separated by the first gap from the gate structure. The first insulating film covering the first side surface of the first pillar is separated by a first gap from the first gate structure. The buried insulating film extends over the first gate structure and the first gap. The buried insulating film buries an upper portion of the first groove.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary schematic plan view of a memory cell array of a semiconductor device in accordance with a first embodiment of the present invention;

FIG. 2A is a fragmentary cross sectional elevation view, taken along an A-A line of FIG. 1, of the memory cell array of FIG. 1;

FIG. 2B is a fragmentary cross sectional elevation view, taken along a B-B line of FIG. 1, of the memory cell array of FIG. 1;

FIG. 3A is a fragmentary cross sectional elevation view, taken along an A-A line of FIG. 1, of a step involved in a method of forming the memory cell array of FIG. 1;

FIG. 3B is a fragmentary cross sectional elevation view, taken along a B-B line of FIG. 1, of the step of FIG. 3A, involved in a method of forming the memory cell array of FIG. 1;

FIG. 4A is a fragmentary cross sectional elevation view, taken along an A-A line of FIG. 1, of a step, subsequent to the step of FIGS. 3A and 3B, involved in a method of forming the memory cell array of FIG. 1;

FIG. 4B is a fragmentary cross sectional elevation view, taken along a B-B line of FIG. 1, of the step of FIG. 4A, involved in a method of forming the memory cell array of FIG. 1;

FIG. 5A is a fragmentary cross sectional elevation view, taken along an A-A line of FIG. 1, of a step, subsequent to the step of FIGS. 4A and 4B, involved in a method of forming the memory cell array of FIG. 1;

FIG. 5B is a fragmentary cross sectional elevation view, taken along a B-B line of FIG. 1, of the step of FIG. 5A, involved in a method of forming the memory cell array of FIG. 1;

FIG. 6A is a fragmentary cross sectional elevation view, taken along an A-A line of FIG. 1, of a step, subsequent to the step of FIGS. 5A and 5B, involved in a method of forming the memory cell array of FIG. 1;

FIG. 6B is a fragmentary cross sectional elevation view, taken along a B-B line of FIG. 1, of the step of FIG. 6A, involved in a method of forming the memory cell array of FIG. 1;

FIG. 7A is a fragmentary cross sectional elevation view, taken along an A-A line of FIG. 1, of a step, subsequent to the step of FIGS. 6A and 6B, involved in a method of forming the memory cell array of FIG. 1;

FIG. 7B is a fragmentary cross sectional elevation view, taken along a B-B line of FIG. 1, of the step of FIG. 7A, involved in a method of forming the memory cell array of FIG. 1;

FIG. 8A is a fragmentary cross sectional elevation view, taken along an A-A line of FIG. 1, of a step, subsequent to the step of FIGS. 7A and 7B, involved in a method of forming the memory cell array of FIG. 1;

FIG. 8B is a fragmentary cross sectional elevation view, taken along a B-B line of FIG. 1, of the step of FIG. 8A, involved in a method of forming the memory cell array of FIG. 1;

FIG. 9A is a fragmentary cross sectional elevation view, taken along an A-A line of FIG. 1, of a step, subsequent to the step of FIGS. 8A and 8B, involved in a method of forming the memory cell array of FIG. 1;

FIG. 9B is a fragmentary cross sectional elevation view, taken along a B-B line of FIG. 1, of the step of FIG. 9A, involved in a method of forming the memory cell array of FIG. 1;

FIG. 10A is a fragmentary cross sectional elevation view, taken along an A-A line of FIG. 1, of a step, subsequent to the step of FIGS. 9A and 9B, involved in a method of forming the memory cell array of FIG. 1;

FIG. 10B is a fragmentary cross sectional elevation view, taken along a B-B line of FIG. 1, of the step of FIG. 10A, involved in a method of forming the memory cell array of FIG. 1;

FIG. 11A is a fragmentary cross sectional elevation view, taken along an A-A line of FIG. 1, of a step, subsequent to the step of FIGS. 10A and 10B, involved in a method of forming the memory cell array of FIG. 1;

FIG. 11B is a fragmentary cross sectional elevation view, taken along a B-B line of FIG. 1, of the step of FIG. 11A, involved in a method of forming the memory cell array of FIG. 1;

FIG. 12A is a fragmentary cross sectional elevation view, taken along an A-A line of FIG. 1, of a step, subsequent to the step of FIGS. 11A and 11B, involved in a method of forming the memory cell array of FIG. 1;

FIG. 12B is a fragmentary cross sectional elevation view, taken along a B-B line of FIG. 1, of the step of FIG. 12A, involved in a method of forming the memory cell array of FIG. 1;

FIG. 13A is a fragmentary cross sectional elevation view, taken along an A-A line of FIG. 1, of a step, subsequent to the step of FIGS. 12A and 12B, involved in a method of forming the memory cell array of FIG. 1;

FIG. 13B is a fragmentary cross sectional elevation view, taken along a B-B line of FIG. 1, of the step of FIG. 13A, involved in a method of forming the memory cell array of FIG. 1;

FIG. 14A is a fragmentary cross sectional elevation view, taken along an A-A line of FIG. 1, of a step, subsequent to the step of FIGS. 13A and 13B, involved in a method of forming the memory cell array of FIG. 1;

FIG. 14B is a fragmentary cross sectional elevation view, taken along a B-B line of FIG. 1, of the step of FIG. 14A, involved in a method of forming the memory cell array of FIG. 1;

FIG. 15A is a fragmentary cross sectional elevation view, taken along an A-A line of FIG. 1, of a step, subsequent to the step of FIGS. 14A and 14B, involved in a method of forming the memory cell array of FIG. 1;

FIG. 15B is a fragmentary cross sectional elevation view, taken along a B-B line of FIG. 1, of the step of FIG. 15A, involved in a method of forming the memory cell array of FIG. 1;

FIG. 16A is a fragmentary cross sectional elevation view, taken along an A-A line of FIG. 1, of a step, subsequent to the step of FIGS. 15A and 15B, involved in a method of forming the memory cell array of FIG. 1;

FIG. 16B is a fragmentary cross sectional elevation view, taken along a B-B line of FIG. 1, of the step of FIG. 16A, involved in a method of forming the memory cell array of FIG. 1;

FIG. 17A is a fragmentary cross sectional elevation view, taken along an A-A line of FIG. 1, of a step, subsequent to the step of FIGS. 16A and 16B, involved in a method of forming the memory cell array of FIG. 1;

FIG. 17B is a fragmentary cross sectional elevation view, taken along a B-B line of FIG. 1, of the step of FIG. 17A, involved in a method of forming the memory cell array of FIG. 1;

FIG. 18A is a fragmentary cross sectional elevation view, taken along an A-A line of FIG. 1, of a step, subsequent to the step of FIGS. 17A and 17B, involved in a method of forming the memory cell array of FIG. 1;

FIG. 18B is a fragmentary cross sectional elevation view, taken along a B-B line of FIG. 1, of the step of FIG. 18A, involved in a method of forming the memory cell array of FIG. 1;

FIG. 19A is a fragmentary cross sectional elevation view, taken along an A-A line of FIG. 1, of a step, subsequent to the step of FIGS. 18A and 18B, involved in a method of forming the memory cell array of FIG. 1;

FIG. 19B is a fragmentary cross sectional elevation view, taken along a B-B line of FIG. 1, of the step of FIG. 19A, involved in a method of forming the memory cell array of FIG. 1;

FIG. 20A is a fragmentary cross sectional elevation view, taken along an A-A line of FIG. 1, of a step, subsequent to the step of FIGS. 19A and 19B, involved in a method of forming the memory cell array of FIG. 1;

FIG. 20B is a fragmentary cross sectional elevation view, taken along a B-B line of FIG. 1, of the step of FIG. 20A, involved in a method of forming the memory cell array of FIG. 1;

FIG. 21A is a fragmentary cross sectional elevation view, taken along an A-A line of FIG. 1, of a step, subsequent to the step of FIGS. 20A and 20B, involved in a method of forming the memory cell array of FIG. 1;

FIG. 21B is a fragmentary cross sectional elevation view, taken along a B-B line of FIG. 1, of the step of FIG. 21A, involved in a method of forming the memory cell array of FIG. 1;

FIG. 22A is a fragmentary cross sectional elevation view, taken along an A-A line of FIG. 1, of a step, subsequent to the step of FIGS. 21A and 21B, involved in a method of forming the memory cell array of FIG. 1;

FIG. 22B is a fragmentary cross sectional elevation view, taken along a B-B line of FIG. 1, of the step of FIG. 22A, involved in a method of forming the memory cell array of FIG. 1;

FIG. 23A is a fragmentary cross sectional elevation view, taken along an A-A line of FIG. 1, of a step, subsequent to the step of FIGS. 22A and 22B, involved in a method of forming the memory cell array of FIG. 1;

FIG. 23B is a fragmentary cross sectional elevation view, taken along a B-B line of FIG. 1, of the step of FIG. 23A, involved in a method of forming the memory cell array of FIG. 1;

FIG. 24A is a fragmentary cross sectional elevation view, taken along an A-A line of FIG. 1, of a step, subsequent to the step of FIGS. 23A and 23B, involved in a method of forming the memory cell array of FIG. 1;

FIG. 24B is a fragmentary cross sectional elevation view, taken along a B-B line of FIG. 1, of the step of FIG. 24A, involved in a method of forming the memory cell array of FIG. 1;

FIG. 25A is a fragmentary cross sectional elevation view, taken along an A-A line of FIG. 1, of a step, subsequent to the step of FIGS. 24A and 24B, involved in a method of forming the memory cell array of FIG. 1;

FIG. 25B is a fragmentary cross sectional elevation view, taken along a B-B line of FIG. 1, of the step of FIG. 25A, involved in a method of forming the memory cell array of FIG. 1;

FIG. 26A is a fragmentary cross sectional elevation view, taken along an A-A line of FIG. 1, of the memory cell array of FIG. 1 in a second embodiment of the present invention;

FIG. 26B is a fragmentary cross sectional elevation view, taken along a B-B line of FIG. 1, of the memory cell array of FIG. 1 in the second embodiment of the present invention;

FIG. 27A is a fragmentary cross sectional elevation view, taken along an A-A line of FIG. 1, of a step involved in a method of forming the memory cell array of FIGS. 1, 26A and 26B;

FIG. 27B is a fragmentary cross sectional elevation view, taken along a B-B line of FIG. 1, of the step of FIG. 27A, involved in a method of forming the memory cell array of FIG. 1;

FIG. 28A is a fragmentary cross sectional elevation view, taken along an A-A line of FIG. 1, of a step, subsequent to the step of FIGS. 27A and 27B, involved in a method of forming the memory cell array of FIGS. 1, 26A and 26B; and

FIG. 28B is a fragmentary cross sectional elevation view, taken along a B-B line of FIG. 1, of the step of FIG. 28A, involved in a method of forming the memory cell array of FIG. 1.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a semiconductor substrate and a first gate structure. The semiconductor substrate has a first groove and a first pillar defined by the first groove. The first groove and the first pillar are adjacent to each other. The first gate structure is disposed in the first groove. The first gate structure includes a first gate insulating film and a first gate electrode. The first gate structure is separated by a first gap from the first pillar.

In some cases, the semiconductor device may further include, but is not limited to, a buried insulating film over the first gate structure and the first gap. The buried insulating film buries an upper portion of the first groove. The first gate structure is disposed in a lower portion of the first groove.

In some cases, the semiconductor device further has a second groove extending in parallel to the first groove and in a first direction, and third and fourth grooves extending in a second direction crossing the first direction. The first pillar is defined by the first, second, third and fourth grooves.

In some cases, the semiconductor device may further include, but is not limited to, a second gate structure in the second groove, the second gate structure including a second gate insulating film and a second gate electrode, the second gate structure being adjacent to the first pillar.

In some cases, the semiconductor device may further include, but is not limited to, a first upper diffusion region disposed in an upper portion of the first pillar; and a first lower diffusion region disposed in a lower portion of the first pillar.

In some cases, the semiconductor device may further include, but is not limited to, a first insulating film in the first groove. The first insulating film covers a first side surface of the first pillar. The first side surface of the first pillar faces toward the gate structure. The first insulating film is separated by the first gap from the gate structure.

In some cases, the first gap is surrounded by the first gate insulating film, the first insulating film and the first buried insulating film.

In some cases, the buried insulating film is lower in gap filling property than the first insulating film and the gate insulating film.

In some cases, the first gap is a vacuum gap.

In some cases, the first insulating film fills the first gap.

In some cases, the first gap is smaller in width than the gate structure, and a total width of the gate structure and the first gap is smaller than a width of the first groove.

In some cases, the third and fourth grooves have bottoms which are deeper than bottoms of the first and second grooves.

In some cases, the semiconductor device may further include, but is not limited to, a first bit line in a lower portion of the third groove; a second insulating film being disposed between the first pillar and the first bit line; a first bit contact in the second insulating film, the first bit contact contacting the first bit line; a first upper diffusion region disposed in an upper portion of the first pillar; and a first lower diffusion region disposed in a lower portion of the first pillar. The first lower diffusion region is electrically coupled through the first bit contact to the first bit line.

In some cases, the semiconductor device may further include, but is not limited to, a bit line burying insulating film in an upper portion of the third groove, the bit line burying insulating film covering the first bit line.

In some cases, the semiconductor device may further include, but is not limited to, a capacitor electrically coupled to the first upper diffusion region.

In another embodiment, a semiconductor device may include, but is not limited to, a semiconductor substrate and a first gate structure. The semiconductor substrate has a first groove and a first pillar defined by the first groove. The first groove and the first pillar are adjacent to each other. The first gate structure is disposed in the first groove. The first gate structure includes a first gate insulating film and a first gate electrode. The first gate structure is separated by a first empty space from the first pillar.

In some cases, the semiconductor device may further include, but is not limited to, a buried insulating film over the first gate structure and the first empty space. The buried insulating film buries an upper portion of the first groove. The first gate structure is disposed in a lower portion of the first groove.

In some cases, the first empty space is a vacuum space.

In another embodiment, a semiconductor device may include, but is not limited to, a semiconductor substrate, a first gate structure, a first insulating film, and a buried insulating film. The semiconductor substrate has first and second grooves extending in a first direction, and third and fourth grooves extending in a second direction crossing the first direction, and a first pillar defined by the first, second, third and fourth grooves. The first gate structure is disposed in a lower portion of the first groove. The first gate structure includes a first gate insulating film and a first gate electrode. The first insulating film is disposed in the first groove. The first insulating film covers a first side surface of the first pillar. The first side surface of the first pillar faces toward the gate structure. The first insulating film is separated by the first gap from the gate structure. The first insulating film covering the first side surface of the first pillar is separated by a first gap from the first gate structure. The buried insulating film extends over the first gate structure and the first gap. The buried insulating film buries an upper portion of the first groove.

In some cases, the semiconductor device may further include, but is not limited to, a first bit line in a lower portion of the third groove; a second insulating film being disposed between the first pillar and the first bit line; a first bit contact in the second insulating film, the first bit contact contacting the first bit line; a first upper diffusion region disposed in an upper portion of the first pillar; and a first lower diffusion region disposed in a lower portion of the first pillar, the first lower diffusion region being electrically coupled through the first bit contact to the first bit line.

In some cases, the semiconductor device may further include, but is not limited to, a bit line burying insulating film in an upper portion of the third groove, the bit line burying insulating film covering the first bit line; and a capacitor electrically coupled to the first upper diffusion region.

In still another embodiment, a method of forming a semiconductor device may include, but is not limited to the following processes. First grooves are formed in a semiconductor substrate. The first grooves extend in a first direction. Lower impurity diffusion regions are formed near the bottoms of the first grooves. Second grooves are formed in the semiconductor substrate to define at least a pillar. The second grooves extend in a second direction crossing the first direction. The pillar is defined by the first and second grooves. First insulating films are formed in the second grooves. The first insulating film covers confronting first and second side surfaces of the second groove and the bottom surface. The first and second side surfaces of the second groove face to each other. The pillar has opposite first and second side surfaces which are covered by the first insulating films in the second grooves. First and second side wall films are concurrently formed, which cover the first insulating films on the first and second side surfaces of the pillar, respectively. Buried insulating films are formed which bury the second grooves having the first and second side wall films. The second side wall film is selectively removed. After that, the first side wall insulating film which is uncovered by the buried insulating film and the first side wall insulating film is selectively removed. A gate insulating film is formed which cover the second side surface of the pillar, the bottom surface of the second groove, and the first side wall film. A conductive film is formed which buries the second groove. The conductive film is then etched back to form a gate electrode in a lower portion of the second groove. The first side wall insulating film is selectively removed to form a gap between the gate electrode and the first side surface of the pillar. An upper diffusion region is formed at the top of the pillar.

In some cases, in the presence of vacuum atmosphere, a gate electrode burying insulating film is formed which buries an upper portion of the groove over the gate electrode and over the gap, so that the gate electrode burying insulating film covers the gate electrode without burying the gap.

In some cases, a gate electrode burying insulating film is formed which buries an upper portion of the groove over the gate electrode and over the gap, so that the gate electrode burying insulating film covers the gate electrode and burying the gap.

In some cases, the first and second side walls are formed by patterning a silicon nitride film. The first insulating film is formed by patterning a silicon oxide film. The buried insulating film is also formed by patterning a silicon oxide film.

In some cases, the selective removal of the second side wall film is carried out by forming an etching mask which protects the first side wall film and exposes a part of the first side wall, and carrying out a etch etching process using an etchant to selectively etch the silicon nitride film so as to selectively remove the second side wall film.

In some cases, the removal of the first side wall film is carried out by carrying out a wet etching process using an etchant to selectively etch the silicon nitride film to selectively etch the first side wall film.

In some cases, a second insulating film is formed which covers inside surfaces of a lower portion of the first groove, and a bit line coupled to the lower diffusion region is formed at a lower portion of the first groove in which the second insulating film is formed before the second groove is formed.

In some cases, a bit line burying insulating film is formed in the first groove. The bit line burying insulating film covers the bit line.

In some cases, a capacitor is formed over the upper diffusion region, wherein the capacitor is electrically coupled to the upper diffusion region.

### First Embodiment

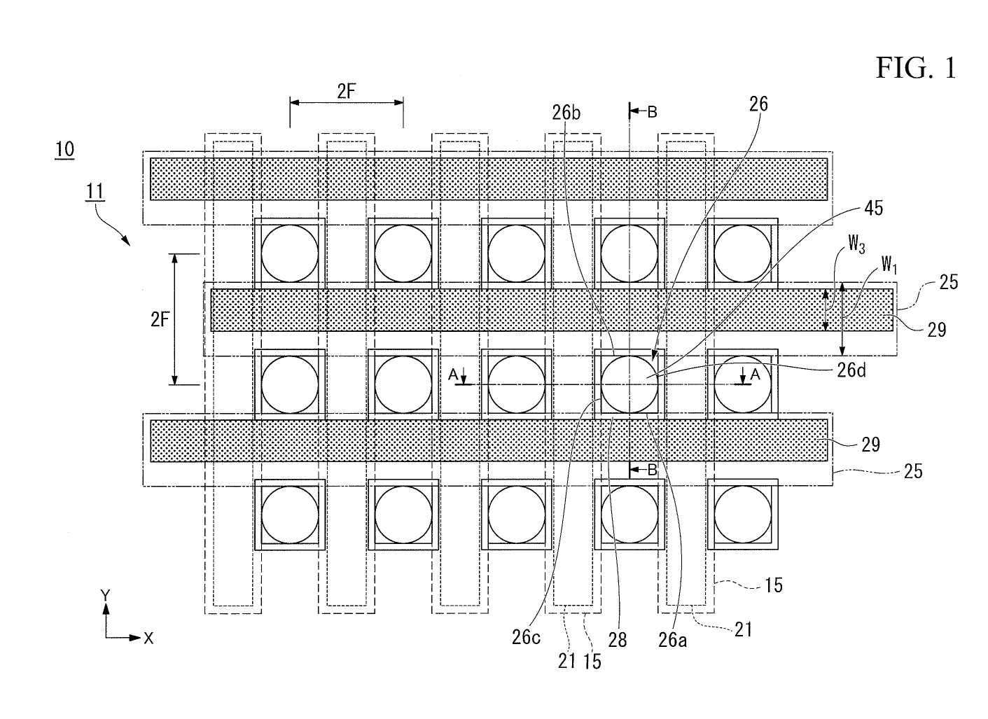

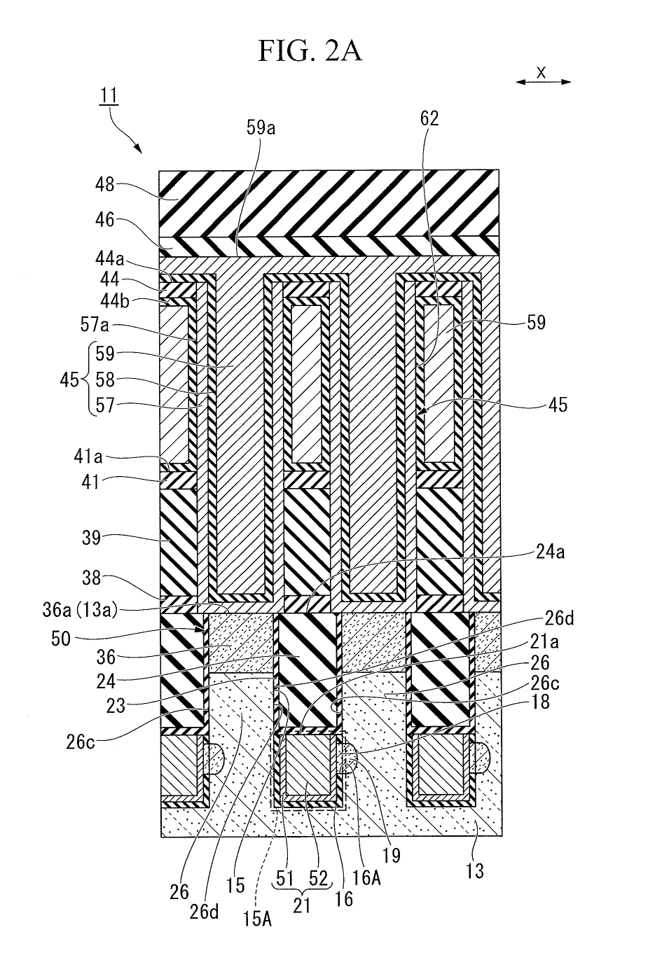

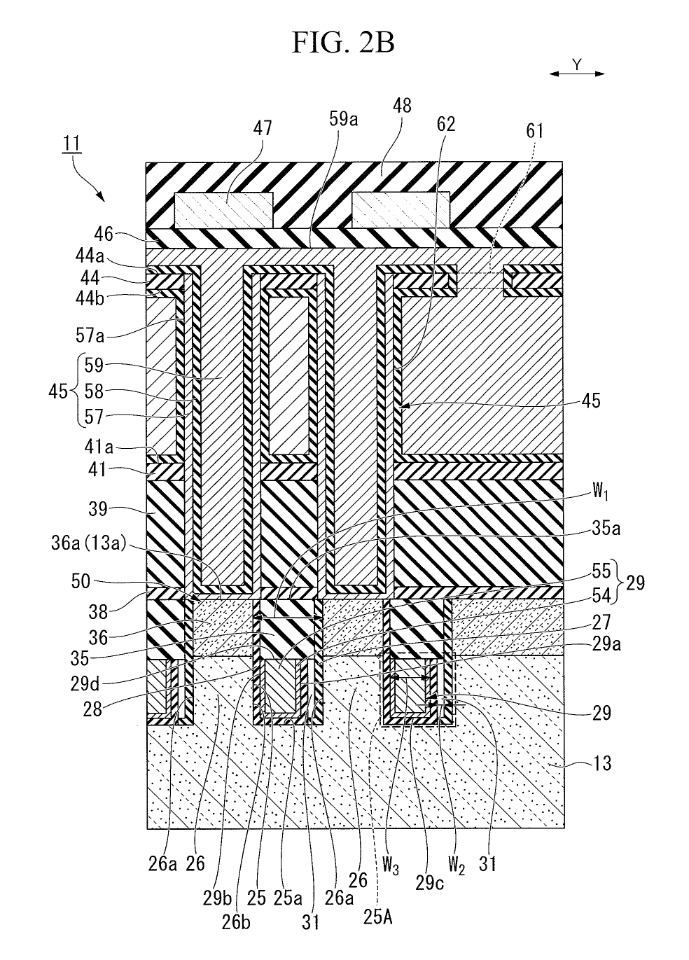

FIG. 1 is a plan view schematically illustrating a memory cell array formed in a semiconductor device according to a first embodiment of the invention. FIG. 2A is a sectional view taken along the line A-A of the memory cell array shown in FIG. 1. FIG. 2B is a sectional view taken along the line B-B of the memory cell array shown in FIG. 1.

In FIG. 1, the X direction represents a direction (second direction) in which a gate electrode 29 extends and the Y direction represents a direction (first direction) in which a bit line 21 intersecting the gate electrode 29 extends.

In order to facilitate the description, FIG. 1 shows only a first groove 15, the bit line 21, a second groove 25, a pillar 26, a gate insulation film 28, the gate electrode 29, and a capacitor 45 among the constituent elements of a memory cell array 11 shown in FIGS. 2A and 2B.

In FIGS. 2A and 2B, the same reference numerals are given to the same constituent elements as those of a semiconductor device 10 according to the first embodiment shown in FIG. 1. In FIGS. 1, 2A, and 2B, a DRAM (Dynamic Random Access Memory) will be described below as an example of the semiconductor device 10 according to the first embodiment.

The semiconductor device 10 according to the first embodiment includes a memory cell region where the memory cell array 11 shown in FIGS. 1, 2A, and 2B is formed and a peripheral circuit region where peripheral circuits (not shown) disposed around the memory cell region are formed. In the peripheral circuit region, peripheral circuit transistors (for example, planar-type transistors) (not shown) are formed.

Next, the configuration of the memory cell array 11 will be described with reference to FIGS. 1, 2A, and 2B.

The memory cell array 11 includes a semiconductor substrate 13, an element isolation region (not shown), the first groove 15, a second insulation film 16, a bit contact 18, a lower impurity diffusion region 19, a bit line 21, an insulation film 23, a buried insulation film 24 for a bit line, the second groove 25, the pillar 26, a first insulation film 27, the gate insulation film 28, the gate electrode 29 which is a buried word line, a void 31, a buried insulation film 35 for a gate electrode, an upper impurity diffusion region 36, a first etching stopper film 38, inter-layer insulation films 39, 46, and 48, a second etching stopper film 41, a support film 44, the capacitor 45, a wiring 47, and a vertical MOS (Metal Oxide Semiconductor) transistor 50.

Referring to FIGS. 2A and 2B, the semiconductor substrate 13 is a substrate that contains impurities of a predetermined concentration. For example, a p-type silicon substrate can be used as the semiconductor substrate. Hereinafter, the p-type silicon substrate will be used as the semiconductor substrate 13 in the following description.

The semiconductor substrate 13 includes an element isolation region (not shown) formed by an element isolation groove (not shown) and an element isolation insulation film (not shown) filling the element isolation groove and a rectangular element formation region formed inside the element isolation region.

A silicon oxide film (SiO₂ film) is used as the element isolation insulation film. The structure of the element isolation region is referred to as an STI (Shallow Trench Isolation). The element isolation region is an active region insulated and isolated by the element isolation region.

Referring to FIGS. 1 and 2A, the first groove 15 is formed in the semiconductor substrate 13. The first groove 15 extends in the Y direction (first direction). The plurality of first grooves 15 are formed in the X direction (second direction). The first groove 15 is a groove that is used to form the bit line 21.

Referring to FIG. 2A, the second insulation film 16 is formed in the inner surface of the lower portion of the first groove 15 corresponding to the region where the bit line 21 is formed. The second insulation film 16 includes an opening 16A in which the bit contact 18 is formed. The opening 16A is formed so that a part of a third side surface 26c of the pillar 26 is exposed. A silicon oxide film (SiO₂ film) can be used as the second insulation film 16.

Referring to FIG. 2A, the bit contact 18 is formed so as to fill the opening 16A formed in the second insulation film 16. For example, a polycrystalline silicon film containing n-type impurities (for example, arsenic (As)) can be used as the material of the bit contact 18.

Referring to FIG. 2A, the lower impurity diffusion region 19 is formed in a portion (in other words, the semiconductor substrate 13 exposed from the opening 16A) coming into contact with the bit contact 18 in the pillar 26. The lower impurity diffusion region 19 is a source/drain region containing n-type impurities (for example, arsenic (As)). In the case of the configuration shown in FIG. 2A, the lower impurity diffusion region 19 serves as a drain region.

Referring to FIG. 2A, the bit line 21 (buried bit line) is formed in a lower portion 15A of the first groove 15 with the second insulation film 16 interposed therebetween and has a flat upper surface 21a. The bit line 21 extends in the Y direction. The plurality of bit lines 21 are formed in the X direction (see FIG. 1).

The bit line 21 has a laminated structure in which a first conductive film 51 coming into contact with the bit contact 18 and functioning as a barrier film and a second conductive film 52 having a resistance value lower than that of the first conductive film 51 are sequentially laminated.

For example, a Ti/TiN laminated film in which a titanium (Ti) film and a titanium nitride (TiN) film are sequentially laminated can be used as the first conductive film 51. For example, tungsten (W) can be used as the second conductive film 52.

The bit line 21 comes into contact with the bit contact 18 and is electrically connected to the lower impurity diffusion region 19 with the bit contact 18 interposed therebetween.

Referring to FIG. 2A, the insulation film 23 is formed so as to cover the upper surface 21a of the bit line 21 and a third side surface 26c and a fourth side surface 26d of the pillar 26 located above the bit line 21. For example, a SiON film can be used as the insulation film 23.

Referring to FIG. 2A, the buried insulation film 24 for a bit line is formed so as to fill the first groove 15 in which the bit line 21 and the insulation film 23 are formed. The upper surface 24a of the buried insulation film 24 for a bit line is a flat surface and is substantially flush with an upper surface 36a (a main surface 13a of the semiconductor 13) of the upper impurity diffusion region 36.

For example, a silicon oxide film (SiO₂ film) formed by an HDP (High Density Plasma) method can be used as the buried insulation film 24 for a bit line.

Referring to FIGS. 1 and 2B, the second groove 25 is formed in the semiconductor substrate 13 so as to extend in the X direction intersecting the first groove 15. The plurality of second grooves 25 are formed in the Y direction. The depth of the second groove 25 is shallower than that of the first groove 15. The width W₁ of the second groove 25 can be set to, for example, 45 nm.

Referring to FIGS. 1, 2A, and 2B, the pillars 26 are surrounded by the first grooves 15 and the second grooves 25 and are formed in a pillar shape. The pillars 26 are formed by processing the first grooves 15 and the second grooves 25 in the semiconductor substrate 13.

As shown in FIG. 1, the pillar 26 has a tetragonal shape in a plan view, and a plurality thereof are provided. The plurality of pillars 26 are disposed so as to be opposite to each other with the second groove 25 interposed therebetween and are formed in a matrix form.

The pillar 26 includes a first side surface 26a and a second side surface 26b, which are exposed by the second grooves 25 and face each other in the Y direction, and the third side surface 26c and the fourth side surface 26d, which are exposed by the first grooves 15 and face each other in the X direction.

Vertical MOS transistors 50, which are three-dimensional transistors, are formed by forming the lower impurity diffusion regions 19, the upper impurity diffusion regions 36, the gate insulation films 28, and the gate electrodes 29 in the plurality of above-described pillars 26. That is, the plurality of vertical MOS transistors 50 are formed in a matrix form in the memory cell array 11.

The vertical MOS transistor 50 has the advantage in that an occupation area is small and a large drain current can be obtained by complete depletion. Accordingly, when the memory cell array 11 includes the plurality of vertical MOS transistors 50, the closest-packed layout of 4F² (where F is the minimum processing dimension) can be realized.

Referring to FIG. 2B, the first insulation film 27 is formed so as to cover the side surface 26a of the pillar 26. In a bottom surface 25a of the second groove 25, the first insulation film 27 comes into contact with the gate insulation film 28. A silicon oxide film (SiO₂ film) can be used as the first insulation film 27. In this case, the thickness of the first insulation film 27 can be set to, for example, 5 nm.

Referring to FIG. 2B, the gate insulation film 28 is formed so as to cover the second side 26b of the pillar 26, side surfaces 29a and 29b of the gate electrode 29 formed in a lower portion 25A of the second groove 25, and a bottom surface 29c of the gate electrode 29. A portion of the gate insulation film 28 covering the bottom surface 29c of the gate electrode 29 is formed in the bottom surface 25a of the second groove 25, and thus comes into contact with the first insulation film 27.

The gate insulation film 28 formed on the side surface 29a (the side surface of the gate electrode 29 facing the first insulation film 27) of the gate electrode 29 is distant from the first insulation film 27 formed in the first side surface 26a of the pillar 26.

For example, a single-layer silicon oxide film (SiO₂ film), a film (SiON film) formed by nitriding a silicon oxide film, a laminated silicon oxide film (SiO₂ film), or a laminated film in which a silicon nitride film (SiN film) is laminated on a silicon oxide film (SiO₂ film) can be used as the gate insulation film 28.

When the single-layer silicon oxide film (SiO₂ film) is used as the gate insulation film 28, the thickness of the gate insulation film 28 can be set to, for example, 5 nm.

Referring to FIG. 2B, the gate electrode 29 has a laminated structure in which a first conductive film 54 functioning as a barrier film and a second conductive film 55 having a resistance value lower than that of the first conductive film 54 are sequentially laminated.

A Ti/TiN laminated film in which a titanium (Ti) film and a titanium nitride (TiN) film are sequentially laminated can be used as the first conductive film 54. Tungsten (W) can be used as the second conductive film 55.

Referring to FIG. 1, the gate electrode 29 extends in the X direction. Only one gate electrode 29 is formed in one second groove 25.

Referring to FIG. 2B, the gate electrode 29 is disposed in the lower portion 25A of the second groove 25 with the gate insulation film 28 interposed therebetween. The gate electrode 29 includes the side surface 29a facing the first insulation film 27 with the gate insulation film 28 interposed therebetween, the side surface 29b coming into contact with the second side surface 26b of the pillar 26 with the gate insulation film 28 interposed therebetween, the bottom surface 29c coming into contact with the bottom surface 25a of the second groove 25 with the gate insulation film 28 interposed therebetween, and a flat upper surface 29d formed below the main surface 13a of the semiconductor substrate 13.

The sides surfaces 29a and 29b and the bottom surface 29c of the gate electrode 29 are covered with the gate insulation film 28. A width W₃ of the gate electrode 29 is set so that the gate insulation film 28 formed on the side surface 29a of the gate electrode 29 does not come into contact with the first insulation film 27 formed on the first side surface 26a of the pillar 26.

Thus, the void 31 can be formed between the gate insulation film 28 formed on the side surface 29a of the gate electrode 29 and the first insulation film 27 formed on the first side surface 26a of the pillar 26. When the width W₁ of the second groove 25 is 45 nm and the thickness of the gate insulation film 28 is 5 nm, the width W₃ of the gate electrode 29 can be set to, for example, 30 nm.

Referring to FIGS. 1 and 2B, the void 31 is formed between the gate insulation film 28 formed on the side surface 29a of the gate electrode 29 and the first insulation film 27 formed on the first side surface 26a of the pillar 26. The void 31 is in a vacuum state (state where the pressure is lower than the atmosphere pressure).

When the width W₁ of the second groove 25 is 45 nm and the width W₃ of the gate electrode 29 is 30 nm, a width W₂ of the void 31 in the Y direction can be set to, for example, 5 nm.

Thus, when one gate electrode 29, which is formed on the second side surface 26b of the pillar 26 located in the lower portion 25A of the second groove 25 with the gate insulation film 28 interposed therebetween and is disposed in one second groove 25, and the void 31, which is formed between the gate insulation film 28 formed on the side surface 29a of the gate electrode 29 and the first insulation film 27 formed on the first side surface 26a of the pillar 26, are provided, the width W₃ of the gate electrode 29 can be sufficiently ensured, compared to a configuration according to the related art in which two gate electrodes electrically insulated from each other are disposed in one groove. Accordingly, it is possible to reduce the resistance value of the gate electrode 29.

In particular, when the pillar 26 is further miniaturized, a channel can be formed in the entire portion located between the upper impurity diffusion region 36 and the lower impurity diffusion region 19 in the pillar 26. Therefore, it is possible to obtain the same advantage as that of a gate electrode having a double gate structure in which one pillar is interposed between both sides.

Further, when the void 31 being in the vacuum state is provided between the gate insulation film 28 formed on the side surface 29a of the gate electrode 29 and the first insulation film 27 formed on the first side surface 26a of the pillar 26, the pillar 26 is formed between the gate electrodes 29. Thus, the capacitance between the gate electrodes 29 can be made to be small by a shield effect of the pillar 26.

Referring to FIG. 2B, the buried insulation film 35 for a gate electrode is formed so as to cover the upper surface 29d of the gate electrode 29 and to fill the second groove 25 located above the upper surface 29d of the gate electrode 29.

An upper surface 35a of the buried insulation film 35 for a gate electrode is flat and is substantially flush with the upper surface 36a (the main surface 13a of the semiconductor 13) of the upper impurity diffusion region 36.

An insulation film formed by a film forming method which does not have good embedding characteristics may be used as the buried insulation film 35 for a gate electrode. Specifically, a silicon oxide film (SiO₂ film) formed by, for example, an HDP method can be used as the buried insulation film 35 for a gate electrode.

By using the insulation film formed by the method, which does not have good embedding characteristics, as the buried insulation film 35 for a gate electrode, the void 31 can be prevented from being filled with the insulation film which becomes the buried insulation film 35 for a gate electrode. In other words, the void 31 can be made to be vacuum by using the insulation film formed by the method, which does not have good embedding characteristics, as the buried insulation film 35 for a gate electrode.

Referring to FIGS. 2A and 2B, the upper impurity diffusion region 36 is formed in the upper portion (specifically, the upper end of the pillar 26) of the pillar 26. The upper surface 36a of the upper impurity diffusion region 36 is configured to be flat and is disposed above the upper surface 29d of the gate electrode 29. The upper surface 36a of the upper impurity diffusion region 36 is a surface corresponding to the main surface 13a of the semiconductor substrate 13.

The upper impurity diffusion region 36 is a source/drain region containing n-type impurities (for example, arsenic (As)). In the case of the configuration of the memory array 11 shown in FIGS. 2A and 2B, the upper impurity diffusion region 36 functions as a source region.

Referring to FIGS. 2A and 2B, the first etching stopper film 38 is formed on the upper end of the insulation film 23, the upper surface 24a of the buried insulation film 24 for a bit line, the upper end of the first insulation film 27, the upper end of the gate insulation film 28, and the upper surface 35a of the buried insulation film 35 for a gate electrode.

A silicon nitride film (SiN film) is used as the first etching stopper film 38. In this case, the thickness of the first etching stopper film 38 can be set to, for example, 50 nm.

Referring to FIGS. 2A and 2B, the inter-layer insulation film 39 is formed on the upper surface of the first etching stopper film 38. A silicon oxide film (SiO₂ film) is used as the inter-layer insulation film 39. In this case, the thickness of the inter-layer insulation film 39 can be set to, for example, 400 nm.

Referring to FIGS. 2A and 2B, the second etching stopper film 41 is formed on the upper surface of the inter-layer insulation film 39. A silicon nitride film (SiN film) is used as the second etching stopper film 41. In this case, the thickness of the second etching stopper film 41 can be set to, for example, 50 nm.

Referring to FIGS. 2A and 2B, the support film 44 is formed above the second etching stopper film 41 so as to be distant from the second etching stopper film 41. A silicon nitride film (SiN film) is used as the support film 44. The support film 44 comes into contact with an outer circumferential side surface 57a on the upper end side of a plurality of lower electrodes 57 described below. Thus, the support film 44 connects the plurality of lower electrodes 57 to each other.

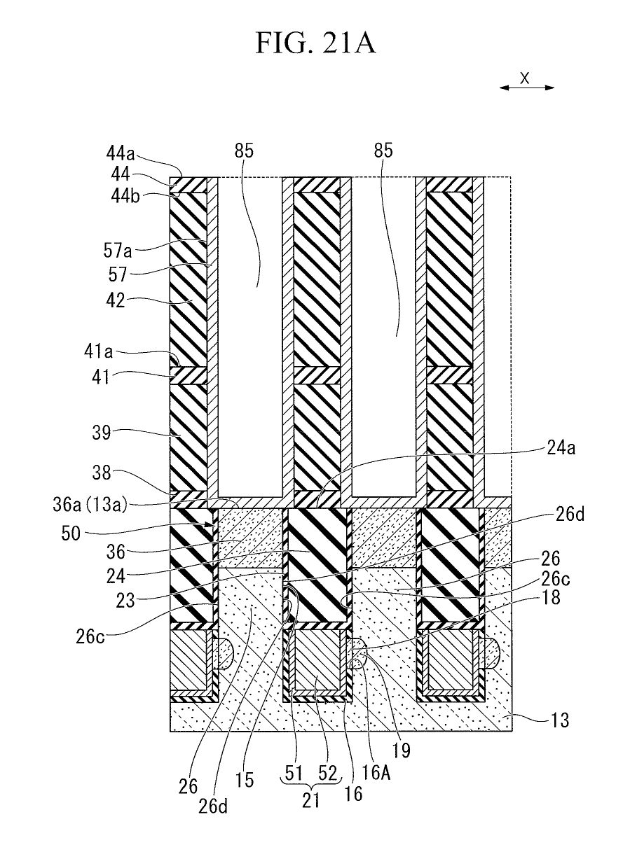

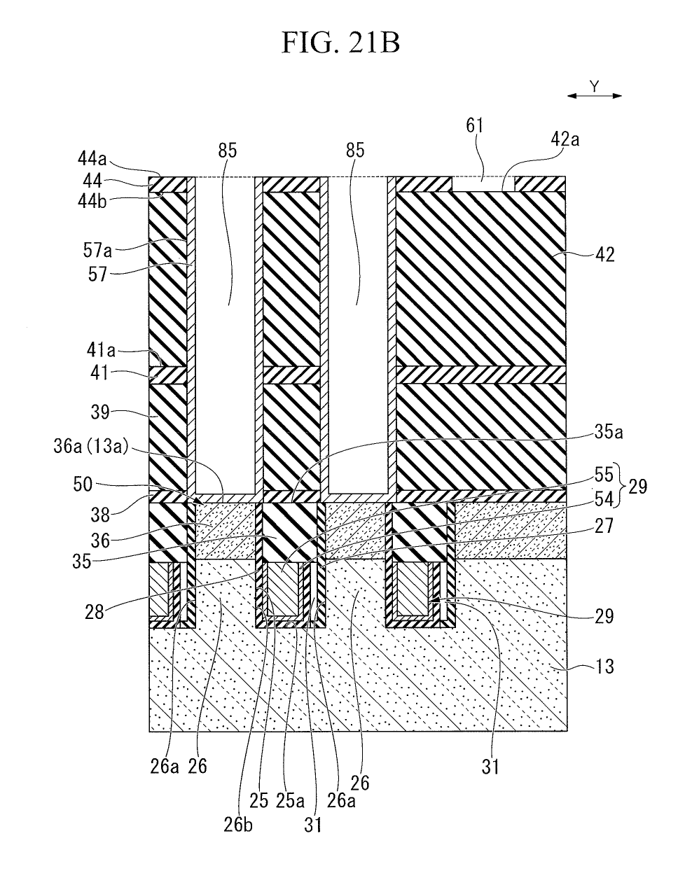

Referring to FIG. 2B, a through portion 61 is formed in the support film 44. The through portion 61 is a port for introducing an etchant used to remove the inter-layer insulation film 42 shown in FIG. 21B described below by wet etching. The inter-layer insulation film 42 is formed in the peripheral circuit region (not shown).

A space 62 is formed between the support film 44 and the second etching stopper film 41 when the inter-layer insulation film 42 is removed. The gap between the support film 44 and the second etching stopper film 41 is identical to the thickness of the inter-layer insulation film 42 shown in FIG. 21B. The gap can be set to, for example, 900 nm.

Further, the thickness of the support film 44 can be set to, for example, 100 μm. In FIG. 2B, only one through portion 61 is illustrated. In effect, the plurality of through portions 61 are formed in the support film 44.

Referring to FIGS. 2A and 2B, the capacitor 45 is an MIM capacitor and is formed on the upper surface 36a of the upper impurity diffusion region 36. One capacitor 45 is formed in each of the plurality of pillars 26. That is, the memory cell array 11 includes the plurality of capacitors 45.

The capacitor 45 includes one lower electrode 57, a capacitive insulation film 58 (in other words, a capacitive insulation film common to the plurality of lower electrodes 57) formed across the plurality of lower electrodes 57, and an upper electrode 59 (in other words, a common upper electrode for the plurality of lower electrodes 57) covering the surface of the capacitive insulation film 58.

The lower electrode 57 has a crown shape. The lower electrode 57 is connected to another lower electrode 57 by the support film 44. For example, a Ti/TiN laminated film in which a titanium (Ti) film and a titanium nitride (TiN) film are sequentially laminated can be used as a film that forms the lower electrode 57.

The capacitive insulation film 58 is formed so as to cover the inner surfaces of the plurality of lower electrodes 57, the outer circumferential side surfaces 57a of the plurality of lower electrodes 57 located between the second etching stopper film 41 and the support film 44, the upper surface 41a of the second etching stopper film 41, the upper surface 44a and the lower surface 44b of the support film 44, and the side surface of the support film 44 that forms the through portion 61.

For example, a laminated film in which an aluminum oxide film (Al₂O₃ film) and a zirconium oxide film (ZrO₂ film) are sequentially laminated can be used as the capacitive insulation film 58.

The upper electrode 59 fills the plurality of lower electrodes 57, the through portion 61, and the space 62 with the capacitive insulation film 58 interposed therebetween and is formed on the capacitive insulation film 58 located on the upper surface 44a of the support film 44.

An upper surface 59a of the upper electrode 59 is configured to be flat. For example, a metal film such as a ruthenium (Ru) film, a tungsten (W) film, or a titanium nitride (TiN) film or a polycrystalline silicon film can be used as a film that forms the upper electrode 59.

Referring to FIGS. 2A and 2B, the inter-layer insulation film 46 is formed on the upper surface 59a of the upper electrode 59. For example, a silicon oxide film (SiO₂ film) can be used as the inter-layer insulation film 46.

The wiring 47 is formed on the upper surface of the inter-layer insulation film 46. The wiring 47 is electrically connected to the upper electrode 59 disposed in the lower layer thereof.

The inter-layer insulation film 48 is formed on the inter-layer film 46 so as to cover the wiring 47. For example, a silicon oxide film (SiO₂ film) can be used as the inter-layer insulation film 48.

In the semiconductor device according to the first embodiment, when one gate electrode 29, which is formed on the second side surface 26b of the pillar 26 located in the lower portion 25A of the second groove 25 with the gate insulation film 28 interposed therebetween and is disposed in one second groove 25, and the void 31, which is formed between the gate insulation film 28 formed on the side surface 29a of the gate electrode 29 and the first insulation film 27 formed on the first side surface 26a of the pillar 26, are provided, the width W₃ of the gate electrode 29 can be sufficiently ensured, compared to the configuration according to the related art in which two gate electrodes electrically insulated from each other are disposed in one groove. Accordingly, it is possible to reduce the resistance value of the gate electrode 29.

Further, the pillar 26 is formed between the gate electrodes 29 by forming the void 31 being in the vacuum state between the gate insulation film 28 formed on the side surface 29a of the gate electrode 29 and the first insulation film 27 formed on the first side surface 26a of the pillar 26. Thus, the capacitance between the gate electrodes 29 can be made to be small by a shield effect of the pillar 26.

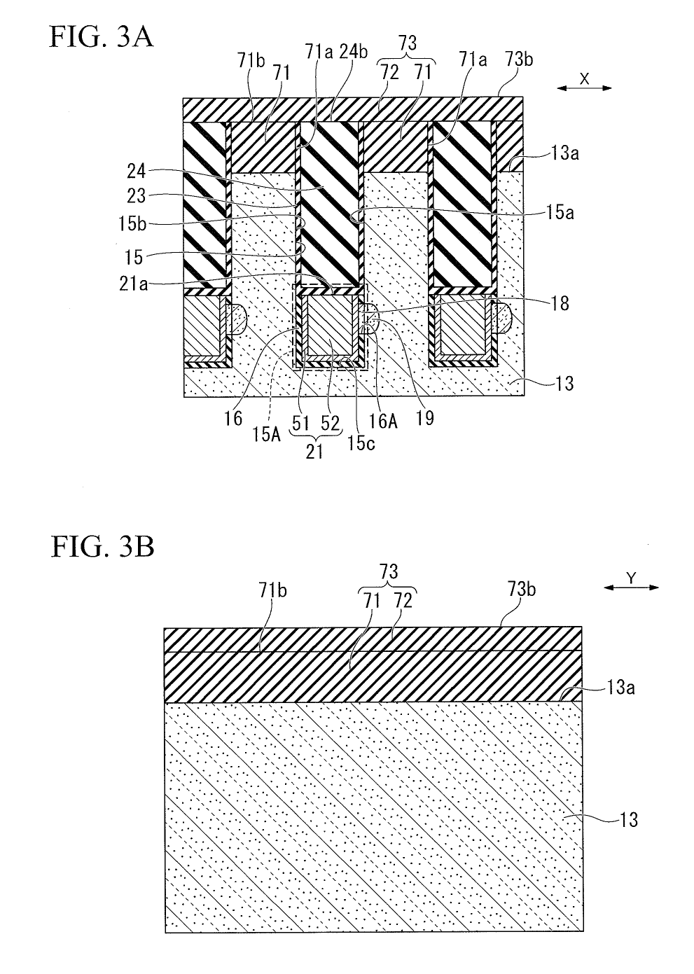

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B are diagrams illustrating steps of manufacturing the memory cell array installed in the semiconductor device according to the first embodiment of the invention.

FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, and 25A are sectional views taken along the cutting line of the memory cell array 11 shown in FIG. 2A.

FIGS. 3B, 4B, 5B, 6B, 7B, 8B, 9B, 10B, 11B, 12B, 13B, 14B, 15B, 16B, 17B, 18B, 19B, 20B, 21B, 22B, 23B, 24B, and 25B are sectional views taken along the cutting line of the memory cell array 11 shown in FIG. 2B.

In FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B, the same reference numerals are given to the same constituent elements as those of the memory cell array 11 shown in FIGS. 2A and 2B.

Next, a method of manufacturing the memory cell array 11 installed in the semiconductor device 10 according to the first embodiment of the invention will be described with reference to FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B.

First, in the steps shown in FIGS. 3A and 3B, the element isolation grooves (not shown) are formed in the semiconductor substrate 13, and then the element isolation insulation films (silicon oxide films (SiO₂ films)) filling the element isolation grooves, so that the element isolation region (not shown) is formed. In this way, the element formation region (active region) disposed inside the element isolation region is formed.

For example, a p-type silicon substrate can be used as the semiconductor substrate 13. Hereinafter, an example will be described in which the p-type silicon substrate is used as the semiconductor substrate 13.

Next, a first hard mask 71 formed of a silicon nitride film having groove-shaped openings 71a is formed on the main surface 13a of the semiconductor substrate 13 by a photolithography technique and dry etching. The openings 71a are formed so as to expose the main surface 13a of the semiconductor substrate 13 corresponding to the regions where the first grooves 15 shown in FIG. 2A are formed.

Next, the plurality of first grooves 15 extending in the Y direction are formed by etching the semiconductor substrate 13 located below the openings 71a by anisotropic etching (specifically, dry etching) using the first hard mask 71 as a mask (see FIG. 1).

Next, the second insulation film 16 is formed so as to cover the inner surface (specifically, the side surfaces 15a and 15b and the bottom surface 15c forming the lower portion 15A) of the lower portion 15A of the first groove 15. Specifically, a silicon oxide film (SiO₂ film) is formed as the second insulation film 16.

In this step, the opening 16A described above with reference to FIG. 2A is not yet formed in the second insulation film 16.

Next, a polycrystalline silicon film (not shown) containing arsenic (As) is formed so as to fill the first groove 15 located lower than the region, where the opening 16A is formed, with the second insulation film 16 interposed therebetween. Subsequently, the opening 16A which exposes the side surface 15a (in other words, the semiconductor substrate 13 corresponding to the region where the pillar 26 is formed) of the lower portion of the first groove 15 is formed by selectively etching the portion corresponding to the region, where the bit contact 18 is formed, in the second insulation film 16.

Subsequently, by growing a polycrystalline silicon film (not shown) containing arsenic (As) on the polycrystalline silicon film (not shown) containing arsenic (As), the first groove 15 is filled with the polycrystalline film (not shown).

Subsequently, the polycrystalline silicon film (not shown) containing arsenic (As) is made to remain only in the opening 16A by selectively removing the polycrystalline silicon film (not shown) containing arsenic (As) formed in the first groove 15 by etching-back.

Thus, the bit contact 18, which is formed of the polycrystalline silicon film (not shown) containing arsenic (As) and comes into contact with the side surface 15a of the lower portion 15A of the first groove 15, is formed in the opening 16A.

Subsequently, the first conductive film 51 and the second conductive film 52 serving as the base material of the bit line 21 are formed in the atmosphere of a predetermined temperature (for example, 650° C.) by a CVD method.

Specifically, a Ti/TiN laminated film in which a titanium (Ti) film and a titanium nitride (TiN) film are sequentially laminated is formed as the first conductive film 51, and then a tungsten (W) film is formed as the second conductive film 52.

The arsenic (As) contained in the bit contact 18 thermally diffuses to the semiconductor substrate 13 corresponding to the lower portion of the first groove 15 by the heat occurring when the first conductive film 51 and the second conductive film 52 are formed. Thus, the lower impurity diffusion region 19 is formed in the lower portion 15A (in other words, the semiconductor substrate 13 becoming the lower portion of the pillar 26) of the first groove 15.

Next, the bit line 21 (see FIG. 1) extending in the Y direction is formed by etching back the first conductive film 51 and the second conductive film 52 and allowing the first conductive film 51 and the second conductive film 52 to remain in the lower portion 15A of the first groove 15.

Next, an insulation film 23 is formed so as to cover the upper surface 21a of the bit line 21, the side surfaces 15a and 15b of the first groove 15 located above the bit line 21, and the surface of the first hard mask 71 forming the side surface of the opening 71a. For example, a SiON film can be used as the insulation film 23.

Next, the buried insulation film 24 for a bit line is formed so as to fill the first groove 15 in which the insulation film 23 is formed and the opening 71a in which the insulation film 23 is formed and so as to have the upper surface 24b substantially flush with the upper surface 71b of the first hard mask 71.

Specifically, the buried insulation film 24 for a bit line is formed so as to have the flat upper surface 24b by filling the first groove 15 and the opening 71a, in which the insulation film 23 is formed, with a silicon oxide film (SiO₂ film) by an HDP (High Density Plasma) method, and then polishing the silicon oxide film (SiO₂ film) by a CMP (Chemical Mechanical Polishing) method until the upper surface 71b of the first hard mask 71 is exposed.

Next, a second hard mask 72 formed of a silicon nitride film is formed so as to cover the upper surface 24b of the buried insulation film 24 for a bit line and the upper surface 71b of the first hard mask 71.

The thickness of the second hard mask 72 can be set to, for example, 15 nm.

In the following description, a hard mask, which is formed by the first hard mask 71 and the second hard mask 72 and is formed of a silicon nitride film, is referred to as a hard mask 73.

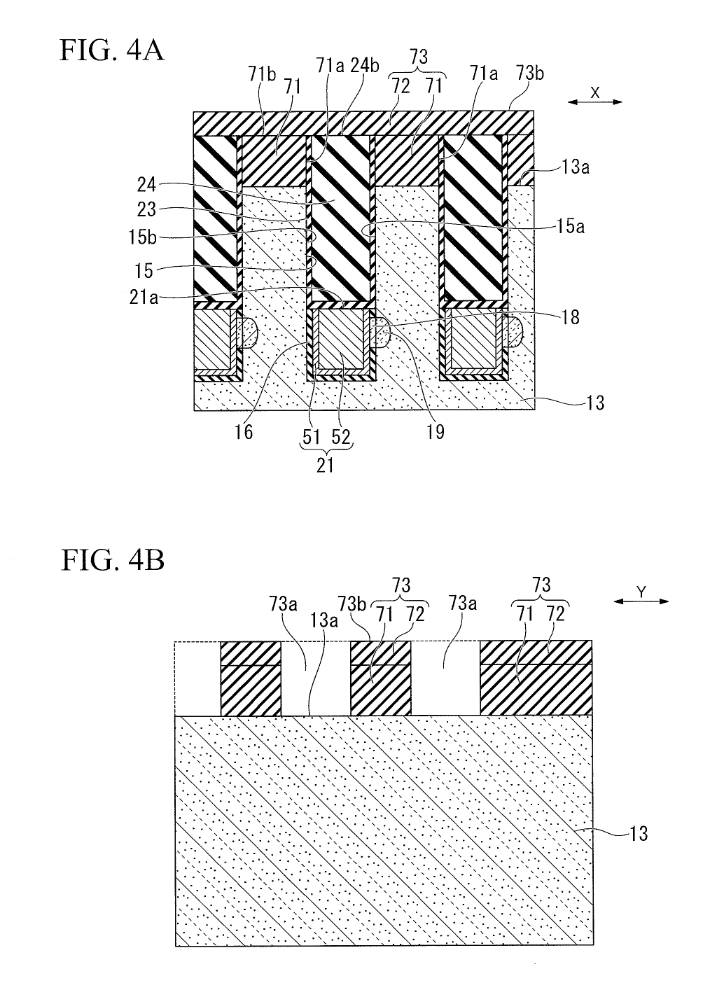

Next, in the steps shown in FIGS. 4A and 4B, groove-shaped openings 73a (openings intersecting the openings 71a) are formed in the hard mask 73 by a photolithography technique and dry etching, as shown in FIG. 4B.

At this time, the openings 73a are formed so as to expose the main surface 13a of the semiconductor substrate 13 corresponding to the regions where the second grooves 25 (see FIG. 2B) are formed.

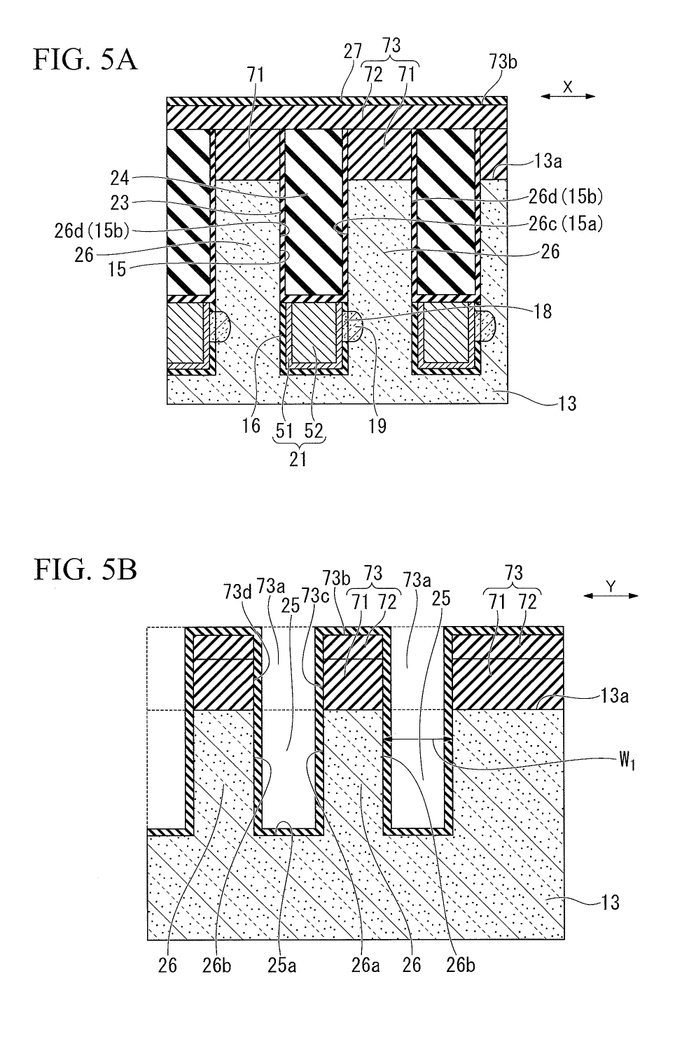

Next, in the steps shown in FIGS. 5A and 5B, the plurality of second grooves 25 extending in the X direction and intersecting the first grooves 15 are formed by etching the semiconductor substrate 13 located below the openings 73a by anisotropic etching (specifically, dry etching) using the hard mask 73 as a mask (see FIG. 1).

Thus, the plurality of pillars 26 are formed, each of which has the first side surface 26a and the second side surface 26b surrounded by the first grooves 15 and the second grooves 25, exposed to the second groove 25, and facing each other and has a lower portion in which the lower impurity diffusion region 19 is formed. The plurality of pillars 26 are formed so as to face each other with the second groove 25 interposed therebetween. The width W₁ of the second groove 25 can be set to, for example, 45 nm.

Next, the first insulation film 27 is formed so as to cover the upper surface 73b and the side surfaces 73c and 73d of the hard mask 73 and the inner surface (specifically, the bottom surface 25a of the second groove 25 and the side surfaces 26a and 26b of the pillar 26) of the second groove 25.

Specifically, a silicon oxide film (SiO₂ film) is formed as the first insulation film 27 by a thermal oxidation method. In this case, the thickness of the first insulation film 27 can be set to, for example, 5 nm.

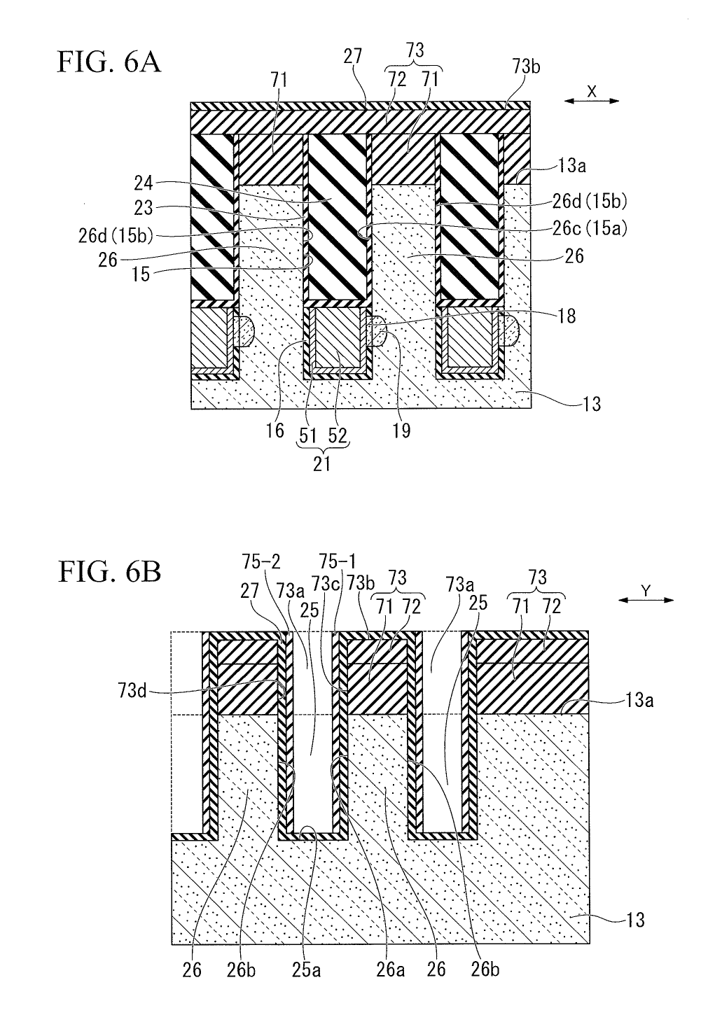

Next, in the steps shown in FIGS. 6A and 6B, a first sidewall film 75-1 is formed so as to cover the first side surface 26a of the pillar 26 and the side surface 73c of the hard mask 73 with the first insulation film 27 interposed therebetween. Simultaneously, a second sidewall film 75-2 is formed so as to cover the second side surface 26b of the pillar 26 and the side surface 73d of the hard mask 73 with the first insulation film 27 interposed therebetween. Thus, the second sidewall film 75-2 faces the first sidewall film 75-1.

Specifically, the first sidewall film 75-1 and the second sidewall film 75-2 are simultaneously formed of a silicon nitride film (SiN film) by forming the silicon nitride film (SiN film) which covers the upper surface (also including the inner surface of the second groove 25) of the structure shown in FIGS. 5A and 5B, and then etching back the entire surface of the silicon nitride film (SiN film).

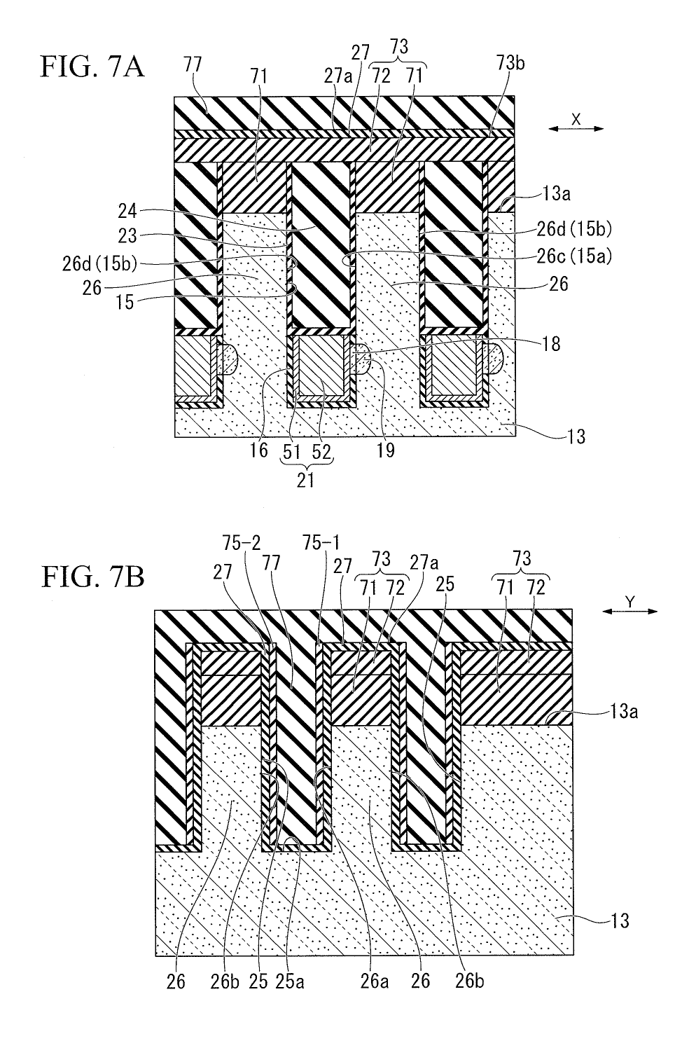

Next, in the steps shown in FIGS. 7A and 7B, the first sidewall film 75-1, the second sidewall film 75-2, and the second groove 25 in which the first insulation film 27 is formed are covered and filled with a buried insulation film 77.

Specifically, the buried insulation film 77 formed of a silicon oxide film (SiO₂ film) is formed by forming the silicon oxide film (SiO₂ film) by an HDP method so as to cover and fill the first sidewall film 75-1 and the second sidewall film 75-2 and the second groove 25 in which the first insulation film 27 is formed.

At this time, an insulation film 76 formed of a silicon oxide film (SiO₂ film) is also formed on the upper surface 27a of the first insulation film 27.

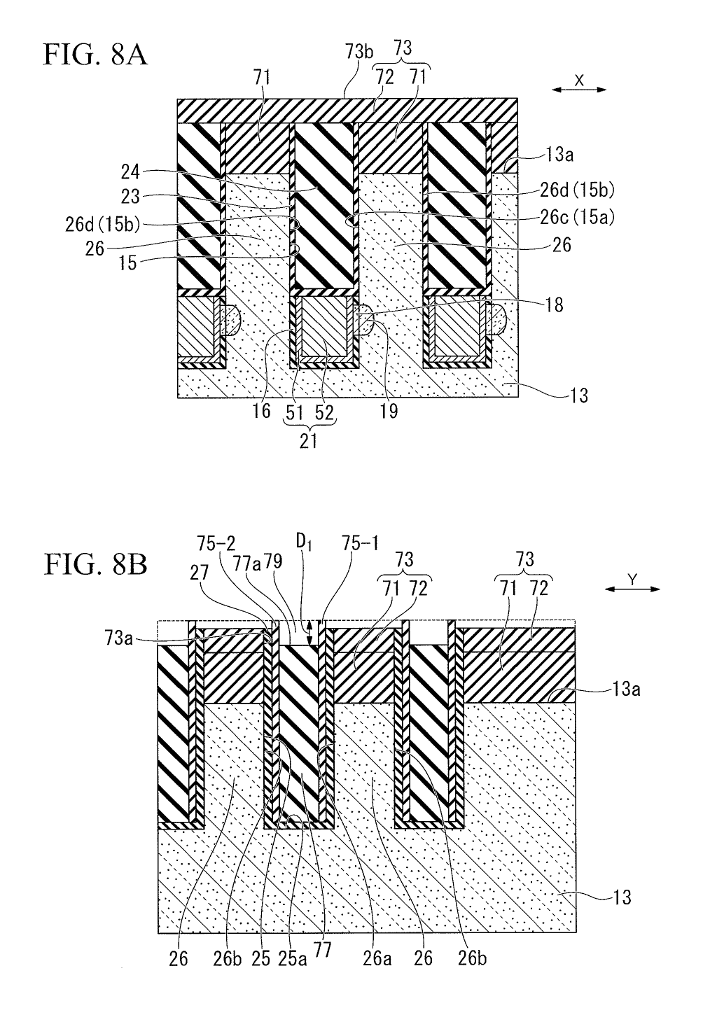

Next, in the steps shown in FIGS. 8A and 8B, a concave portion 79 is formed by removing the first insulation film 27 formed on the upper surface 73b of the hard mask 73 and the buried insulation film 77 (both of which are formed of the silicon oxide film (SiO₂ film)) and removing a part of the buried insulation film 77 formed on the upper end of the opening 73a by etching-back performed under the condition in which the silicon oxide film is selectively etched.

At this time, the etching-back is performed so that the upper surface 77a of the buried insulation film 77 subjected to the etching-back is located between the upper surface 73b of the hard mask 73 and the main surface 13a of the semiconductor substrate 13. A depth D₁ of the concave portion 79 can be set to, for example, 30 nm with reference to the upper end surfaces of the first sidewall film 75-1 and the second sidewall film 75-2.

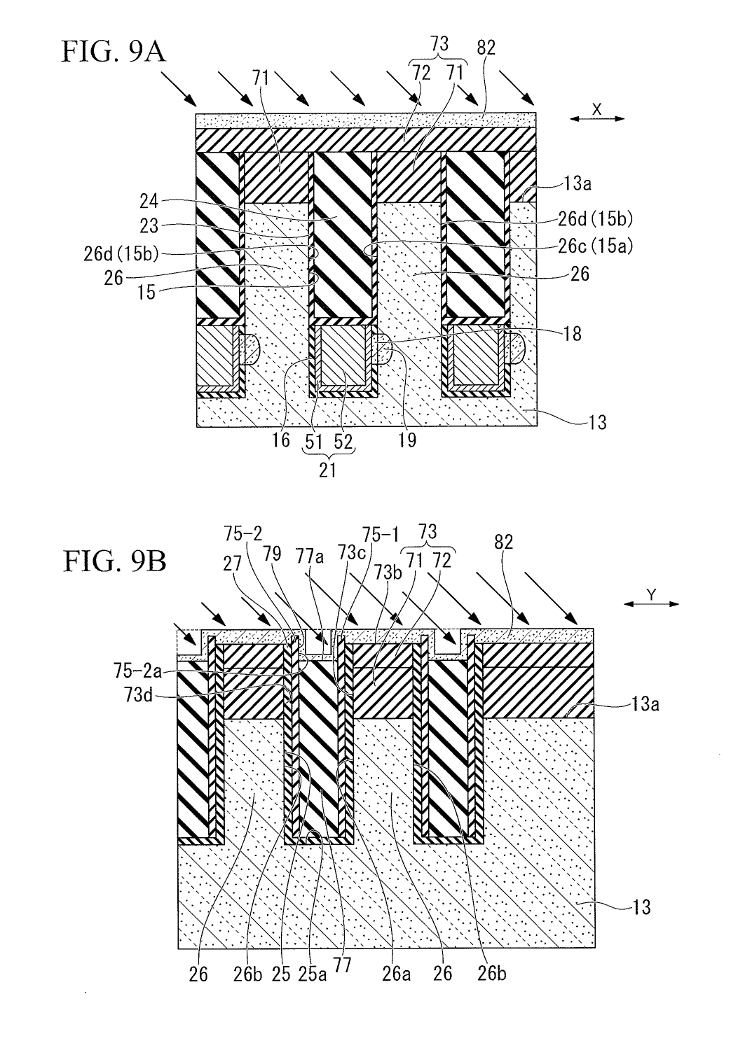

Next, in the steps shown in FIGS. 9A and 9B, an amorphous silicon film 82 is formed so as to cover the upper end surface of the first insulation film 27, the upper surface 73b of the hard mask 73, the first sidewall film 75-1 and the second sidewall film 75-2 protruding from the upper surface 77a of the buried insulation film 77, and the inner surface of the concave portion 79.

Specifically, the amorphous silicon film 82 is formed by an LP-CVD (Low Pressure Chemical Vapor Deposition) method.

At this time, the thickness of the amorphous silicon film 82 is set to the extent that the concave portion 79 is not completely covered. When a depth D₁ of the concave portion 79 is 30 nm, the thickness of the amorphous silicon film 82 can be set to, for example, 10 nm.

Subsequently, ions are implanted into the amorphous silicon film 82 by performing skew ion implantation in a direction in which ions are not implanted into the amorphous silicon film 82 formed on the side surface of the second sidewall film 75-2 facing the first sidewall film 75-1.

Thus, the etching speed of the amorphous silicon film 82 into which the ions are implanted can be made to be slower than the etching speed of the amorphous silicon film 82 into which ions are not implanted.

For example, BF2 can be used as a kind of ion. In this case, the energy of the skew ion implantation can be set to, for example, 5 KeV. In this case, an implantation angle α can appropriately be selected in a range from 15 degrees to 30 degrees.

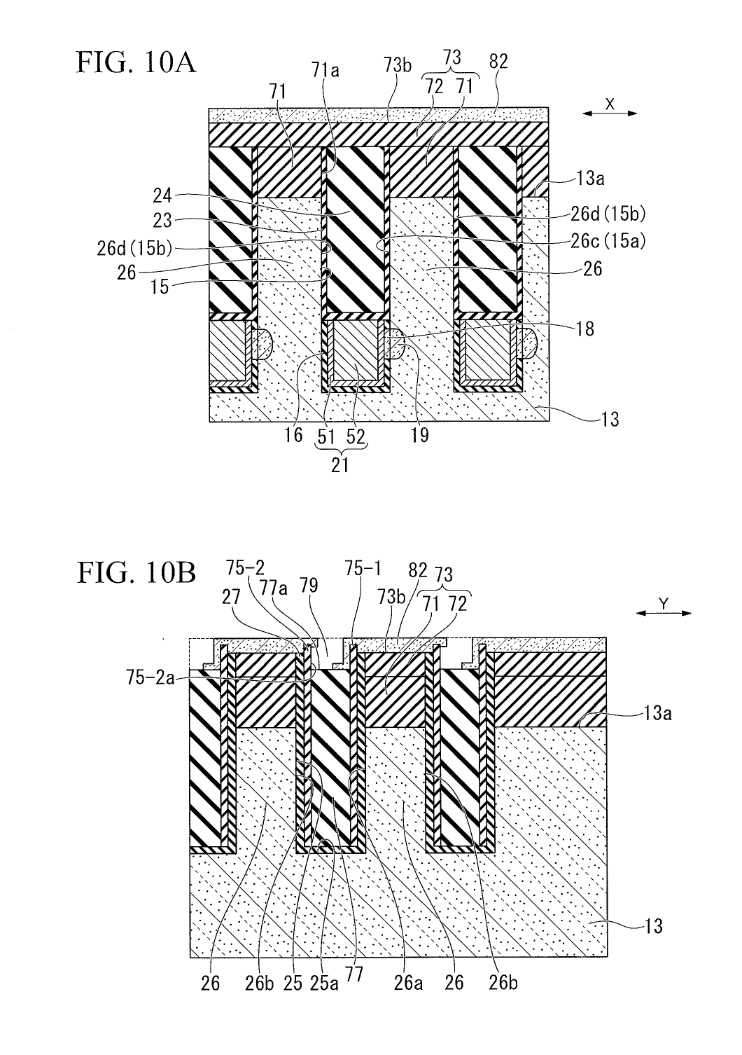

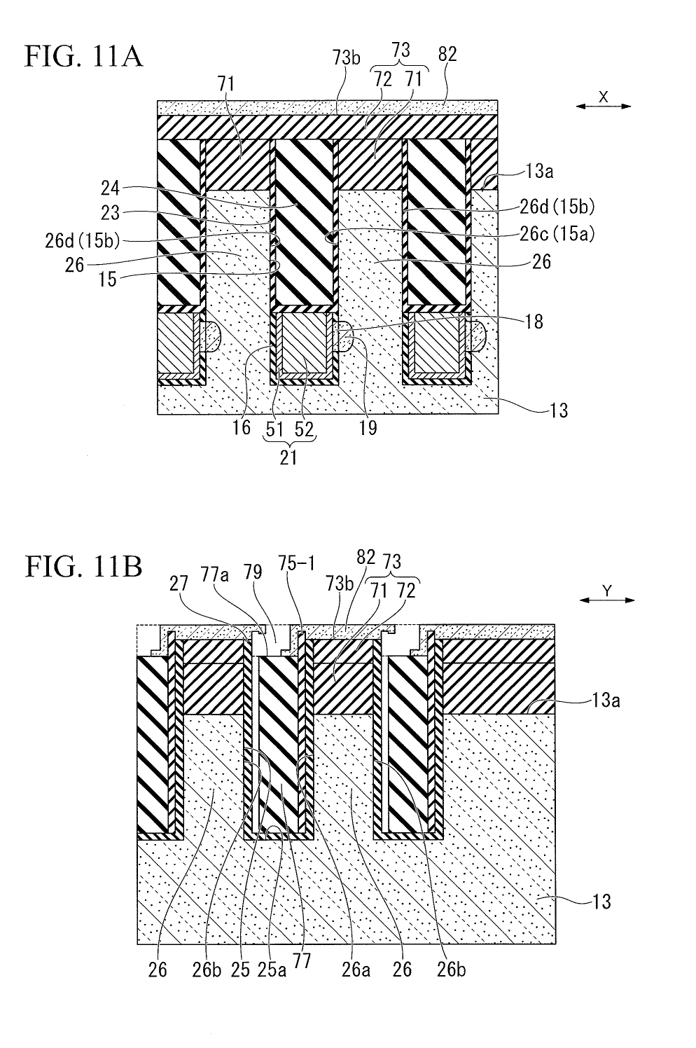

Next, in the steps shown in FIGS. 10A and 10B, a side surface 75-2a of the second sidewall film 75-2 is exposed from the amorphous silicon film 82 by selectively removing a portion (portion in which the etching speed is fast), into which the ions are not implanted, in the amorphous silicon film 82 by wet etching, as shown in FIG. 10B.

For example, ammonia water can be used as an etchant used when the amorphous silicon film 82 is selectively removed.

The etching speed of the amorphous silicon film 82 covering the first sidewall film 75-1 is slower than that of the amorphous silicon film 82 into which the ions are not implanted, since the ions are implanted into the amorphous silicon film 82 covering the first sidewall film 75-1 in the steps described above with reference to FIGS. 9A and 9B. Therefore, after the wet etching, the first sidewall film 75-1 remains to be covered with the amorphous silicon film 82.

The amorphous silicon film 82 shown in FIGS. 10A and 10B functions as an etching mask in the steps described later with reference to FIGS. 11A and 11B.

Next, in the steps shown in FIGS. 11A and 11B, the second sidewall film 75-2 is selectively removed by the wet etching performed using the amorphous silicon film 82 shown in FIGS. 10A and 10B as an etching mask.

Specifically, the second sidewall film 75-2 formed of a silicon nitride film (SiN film) is removed by hot phosphoric acid using the amorphous silicon film 82 shown in FIGS. 10A and 10B as an etching mask. At this time, only the second sidewall film 75-2 is selectively etched, since the first sidewall film 75-1 formed of the silicon nitride film (SiN film) is covered with the amorphous silicon film 82.

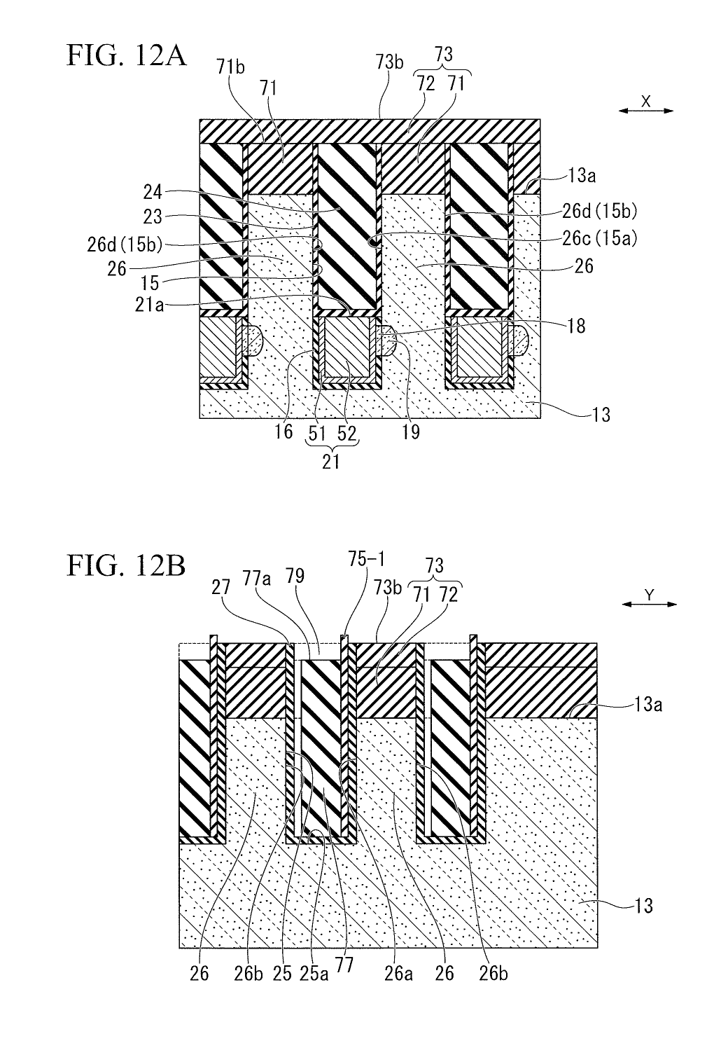

Next, in the steps shown in FIGS. 12A and 12B, the ion-implanted amorphous silicon film 82 is selectively removed by dry etching.

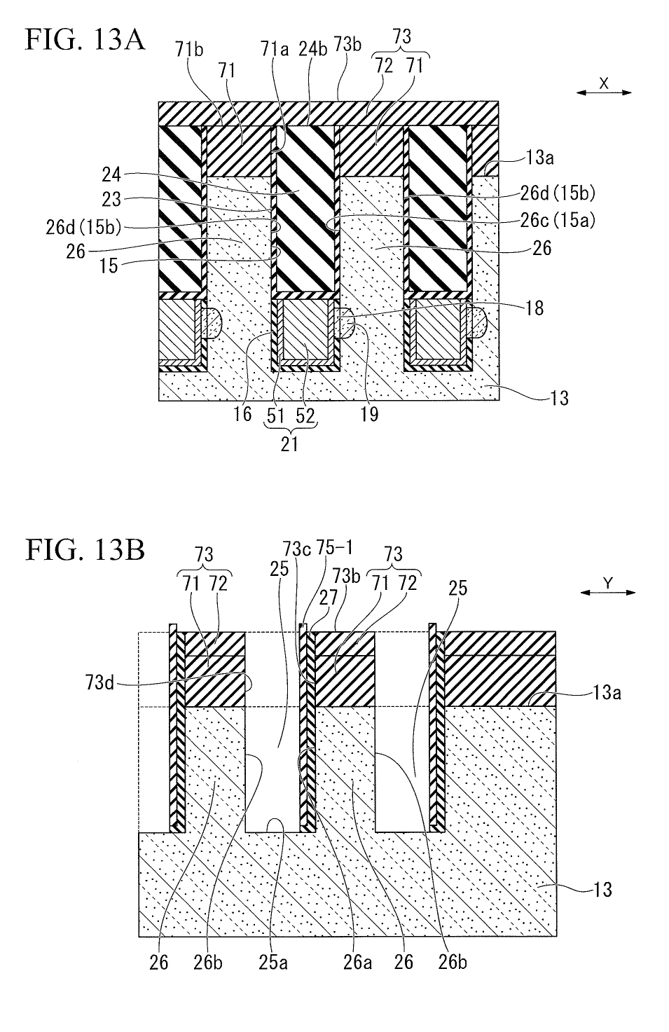

Next, in the steps shown in FIGS. 13A and 13B, the buried insulation film 77 formed of the silicon oxide film (SiO₂ film) in FIG. 12B is removed by wet etching performed using an etchant with which the silicon oxide film (SiO₂ film) is selectively etched.

At this time, the upper end surface of the insulation film 23 shown in FIG. 13A and the upper surface 24b of the buried insulation film 24 for a bit line are covered with the second hard mask 72 formed of the silicon nitride film (SiN film).

For this reason, the insulation film 23 formed of the silicon oxide film (SiO₂ film) and the buried insulation film 24 for a bit line are not etched by the wet etching in which the buried insulation film 77 is removed.

Further, the first insulation film 27 (silicon oxide film (SiO₂ film)) which is not covered with the first sidewall film 75-1 is removed along with the buried insulation film 77 by the above wet etching.

Thus, a part of the bottom surface 25a of the second groove 25, the side surface 26b of the pillar 26, and the side surface 73d of the hard mask 73 are exposed.

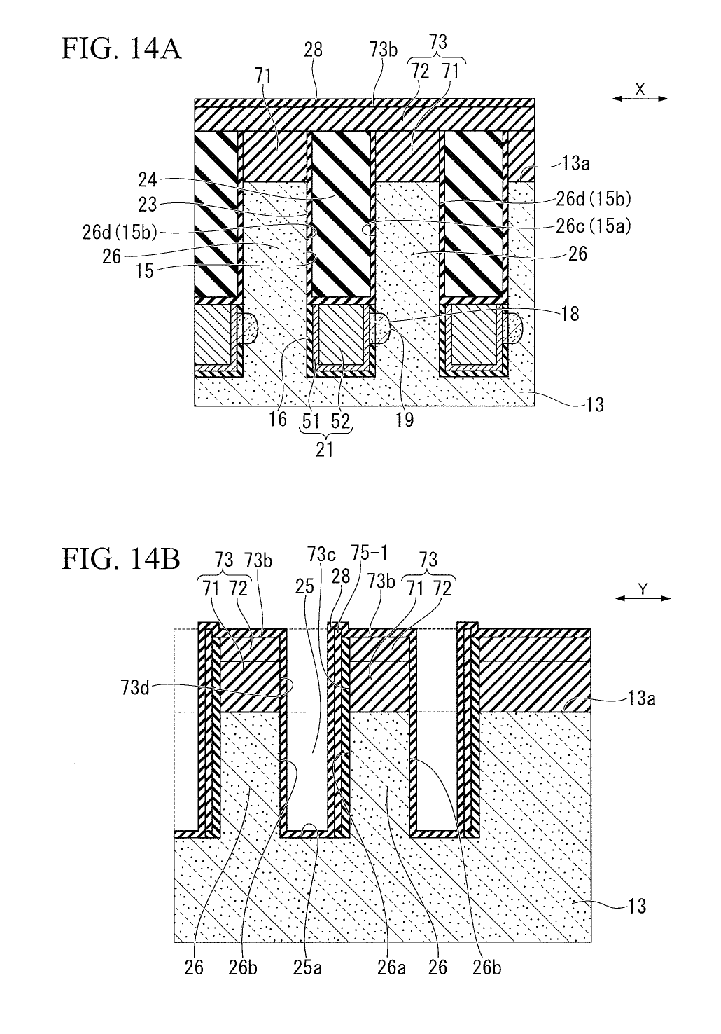

Next, in the steps shown in FIGS. 14A and 14B, the gate insulation film 28 is formed so as to cover the bottom surface 25a of the second groove 25, the upper surface 73b and the side surface 73d of the hard mask 73, and the first sidewall film 75-1.

A single-layer silicon oxide film (SiO₂ film), a film (SiON film) formed by nitriding a silicon oxide film, a laminated silicon oxide film (SiO₂ film), or a laminated film in which a silicon nitride film (SiN film) is laminated on a silicon oxide film (SiO₂ film) can be used as the gate insulation film 28.

When the single-layer silicon oxide film (SiO₂ film) is used as the gate insulation film 28, the thickness of the gate insulation film 28 can be set to, for example, 5 nm.

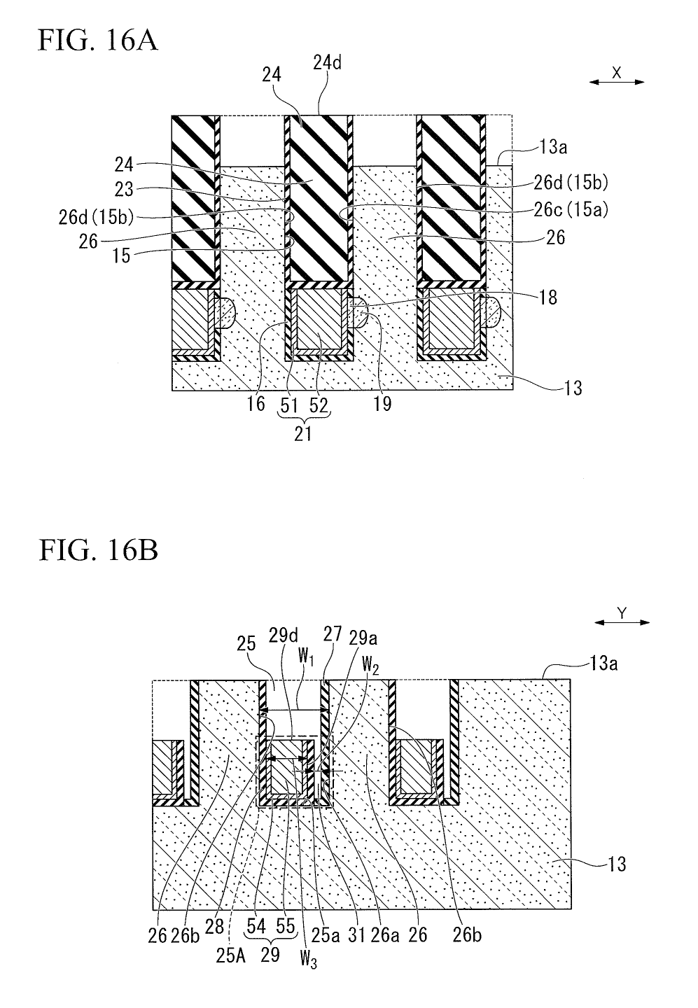

In this step, the gate insulation film 28 is formed in a region broader than the region where the gate insulation film 28 described above with reference to FIG. 2B is formed. The gate insulation film 28 shown in FIG. 14B is patterned in the steps described later in FIGS. 16A and 16B to become the gate insulation film 28 shown in FIG. 2B.

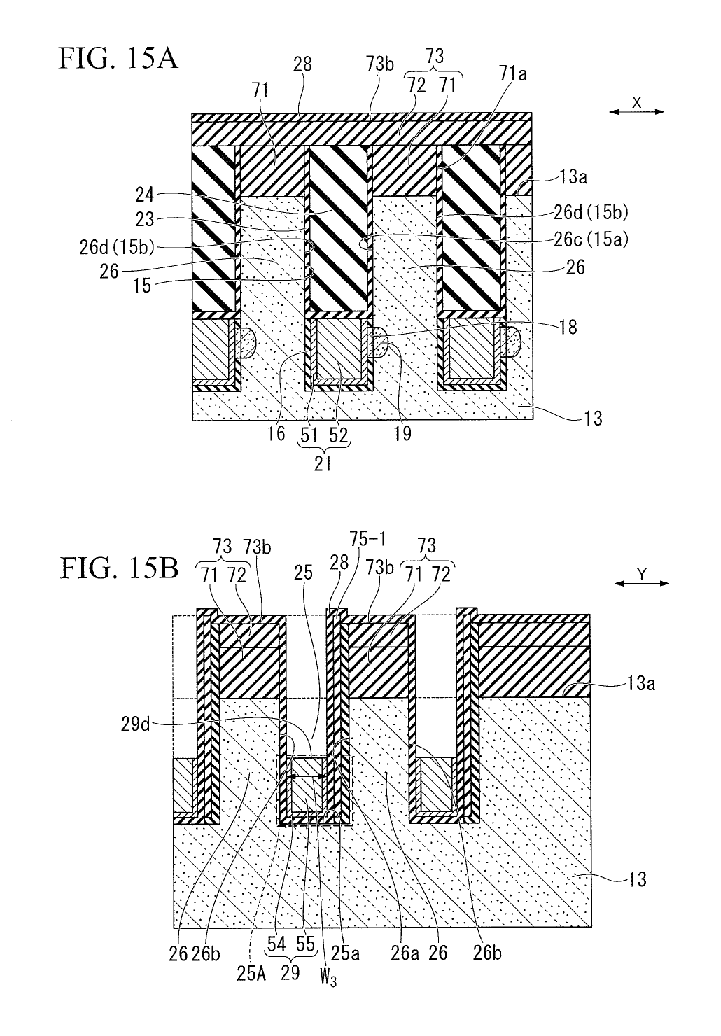

Next, in the steps shown in FIGS. 15A and 15B, the second groove 25 is filled by a CVD method by sequentially forming the first conductive film 54, which functions as a barrier film, and the second conductive film 55, which has a resistance value lower than that of the first conductive film 54, inside the second groove 25 in which the gate insulation film 28 is formed. The first conductive film 54 and the second conductive film 55 are the base materials of the gate electrode 29.

Specifically, a Ti/TiN laminated film in which a titanium (Ti) film and a titanium nitride (TiN) film are sequentially laminated is formed as the first conductive film 54, and then a tungsten (W) film is formed as the second conductive film 55.

Subsequently, the first conductive film 54 and the second conductive film 55 are made to remain in the lower portion 25A of the second groove 25 by etching back the entire surface of the first conductive film 54 and the second conductive film 55. Thus, one gate electrode 29 including the first conductive film 54 and the second conductive film 55 is formed in the lower portion 25A of the second groove 25 with the gate insulation film 28 interposed therebetween.

At this time, the upper surface 29d of the gate electrode 29 is subjected to the above etching-back so that the upper surface 29d of the gate electrode 29 is located below the main surface 13a of the semiconductor substrate 13.

When the width W₁ of the second groove 25 is 45 nm, the width W₃ of the gate electrode 29 can be set to, for example, 30 nm.

Accordingly, by forming the first conductive film 54 and the second conductive film 55 filling the second groove 25, etching back the entire surfaces of the first conductive film 54 and the second conductive film 55, and forming one gate electrode 29 including the first conductive film 54 and the second conductive film 55 in the lower portion 25A of the second groove 25, the width W₃ of the gate electrode 29 can be sufficiently ensured, thereby reducing the resistance value of the gate electrode 29, compared to a double date structure (structure in which two gate electrodes are disposed in one groove) according to the related art in which dry etching is performed to divide a conductive film filling one groove into two films.

In particular, when the pillar 26 is further miniaturized, a channel can be formed in the entire portion located between the upper impurity diffusion region 36 and the lower impurity diffusion region 19 in the pillar 26. Therefore, it is possible to obtain the same advantage as that of a gate electrode having a double gate structure in which one pillar is interposed between both sides.

Next, in the steps shown in FIGS. 16A and 16B, the gate insulation film 28 and the first insulation film 27 formed above the main surface 13a of the semiconductor substrate 13 are removed by anisotropic etching (specifically, dry etching) in which the silicon oxide film (SiO₂ film) can selectively be etched.

Subsequently, the hard mask 73 exposed from the gate insulation film 28 and the first insulation film 27 and formed of the silicon nitride film (SiN film) and the first sidewall film 75-1 are selectively removed by wet etching using hot phosphoric acid.

Thus, the void 31 is formed between the gate insulation film 28 formed on the side surface 29a of the gate electrode 29 and the first insulation film 27 formed on the first side surface 26a of the pillar 26.

When the width W₁ of the second groove 25 is 45 nm and the width W₃ of the gate electrode 29 is 30 nm, the width W₂ of the void 31 can be set to, for example, 5 nm.

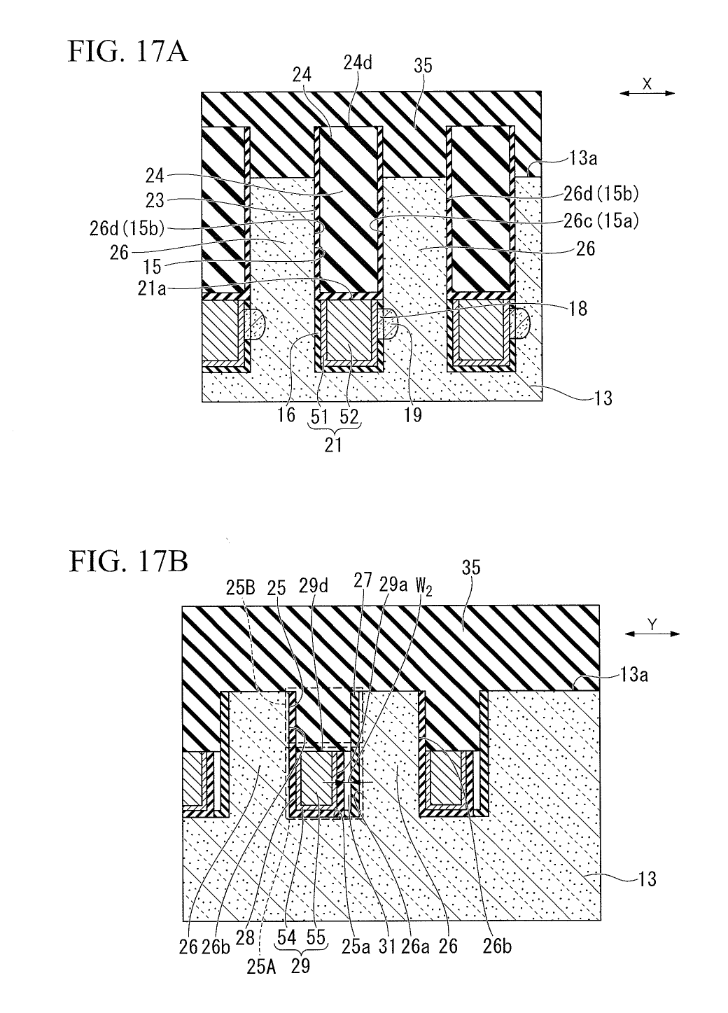

Next, the steps shown in FIGS. 17A and 17B, the buried insulation film 35 of the gate electrode is formed using a film forming apparatus (not shown), which does not have good embedding characteristics, under the vacuum atmosphere so as to fill the upper portion 25B of the second groove 25, in which the first insulation film 27, the gat insulation film 28, and the gate electrode 29 are formed, and so as not to fill the void 31 formed in the lower portion 25A of the second groove 25.

In this step, the buried insulation film 35 for a gate electrode is formed even at the position above the main surface 13a of the semiconductor substrate 13.

Specifically, the buried insulation film 35 for a gate electrode is formed by forming a silicon oxide film (SiO₂ film) using an HDP-CVD apparatus which does not have good embedding characteristics.

Thus, when the upper portion 25B of the second groove 25 located above the void 31 is filled with the buried insulation film 35 for a gate electrode, which is formed using the film forming apparatus (not shown) not good in the burying characteristic, under the vacuum atmosphere, the void 31 with the narrow width W₂ is not filled with the buried insulation film 35 for a gate electrode. Accordingly, the void 31 can be made to be in the vacuum state.

When the void 31 being in the vacuum state is formed between the gate insulation film 28 formed on the side surface 29a of the gate electrode 29 and the first insulation film 27 formed on the first side surface 26a of the pillar 26, the pillar 26 is interposed between the gate electrodes 29 adjacent to each other in the first direction. Accordingly, it is possible to reduce the capacitance between the gate electrodes 29 by the shield effect of the pillar 26.

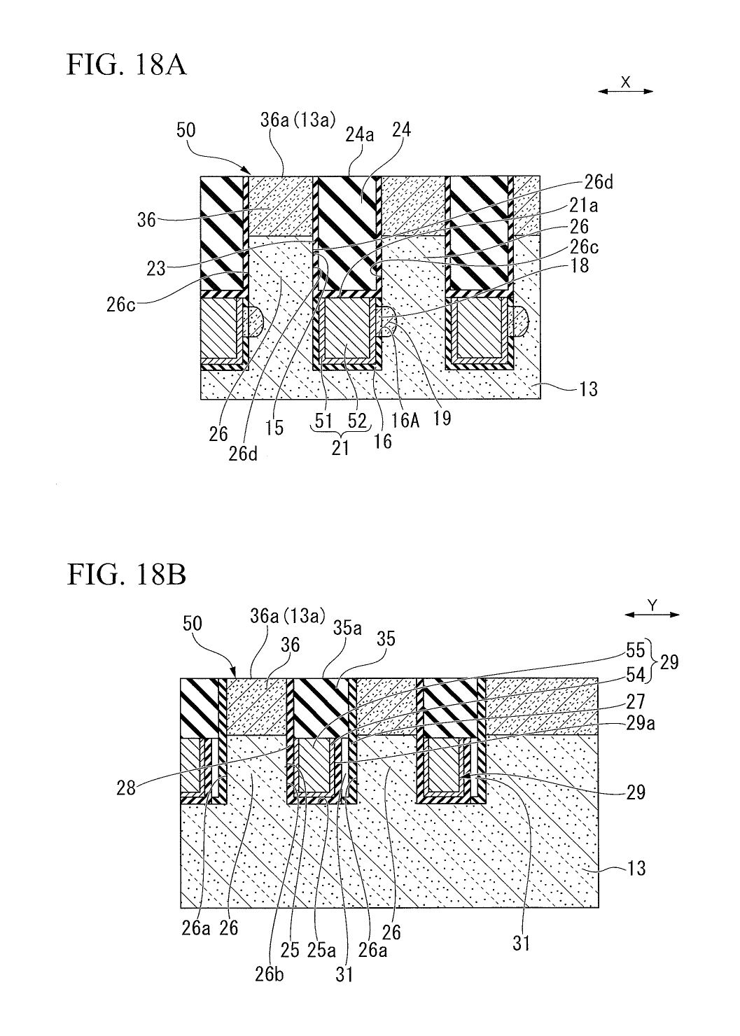

Next, in the steps shown in FIGS. 18A and 18B, the main surface 13a of the semiconductor substrate 13 is exposed by removing the insulation film 23, the buried insulation film 24 for a bit line, and the buried insulation film 35 for a gate electrode (in other words, all of which are unnecessary insulation films) formed above the upper surface of the pillar 26 which is the main surface 13a of the semiconductor substrate 13 shown in FIGS. 17A and 17B by etching-back performed under the condition in which a silicon oxide film (silicon oxide film (SiO₂ film)) can selectively be etched.

Thus, the upper end surface of the insulation film 23, the upper surface 24a of the buried insulation film 24 for a bit line, and the upper surface 35a of the buried insulation film 35 for a gate electrode are substantially flush with the main surface 13a of the semiconductor substrate 13.

Subsequently, the upper impurity diffusion region 36 is formed in the upper portion (specifically, the upper end) of the pillar 26 by doping arsenic (As) as n-type impurities to the main surface 13a of the semiconductor substrate 13 which is the upper surface of the pillar 26, and then thermally diffusing the arsenic (As). Thus, the vertical MOS transistors 50 are formed in the plurality of pillars 26.

The upper surface 36a of the upper impurity diffusion region 36 is substantially flush with the upper surface (the main surface 13a of the semiconductor substrate 13) of the pillar 26.

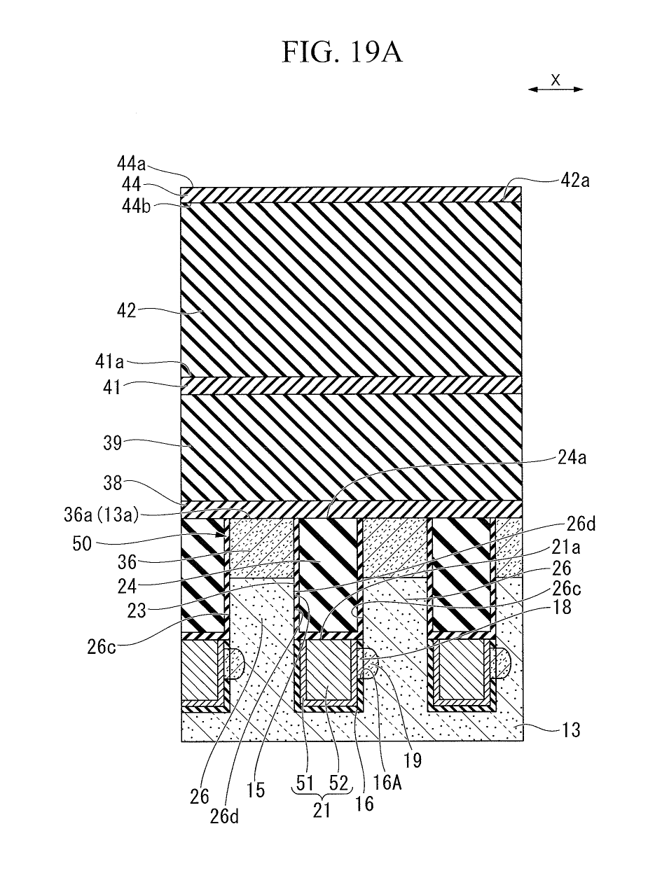

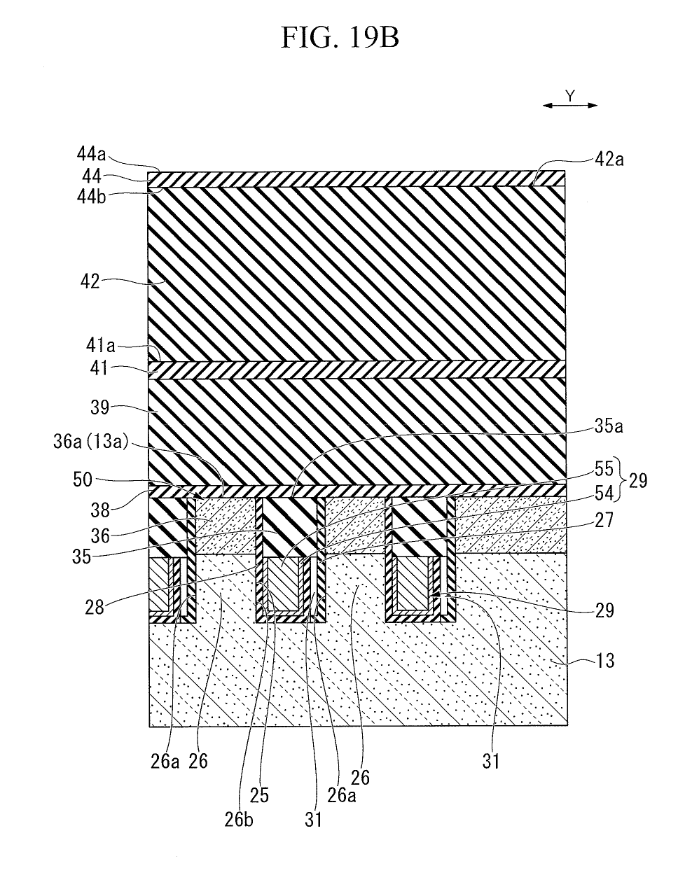

Next, in the steps shown in FIGS. 19A and 19B, a planar-type transistor (not shown) is formed as a transistor for a peripheral circuit in the peripheral circuit region (not shown) by a known method.

Subsequently, the first etching stopper film 38, the inter-layer insulation film 39, the second etching stopper film 41, and the inter-layer insulation film 42, and the support film 44 are sequentially formed on the structure shown in FIGS. 18A and 18B in which the transistor for the peripheral circuit is formed.

Specifically, for example, a silicon nitride film (SiN film) with a thickness of 50 nm, a silicon oxide film (SiO₂ film) with a thickness of 400 nm, a silicon nitride film (SiN film) with a thickness of 50 nm, a silicon oxide film (SiO₂ film) with a thickness of 900 nm, and a silicon nitride film (SiN film) with a thickness of 100 nm are sequentially formed as the first etching stopper film 38, the inter-layer insulation film 39, the second etching stopper film 41, the inter-layer insulation film 42, and the support film 44, respectively.

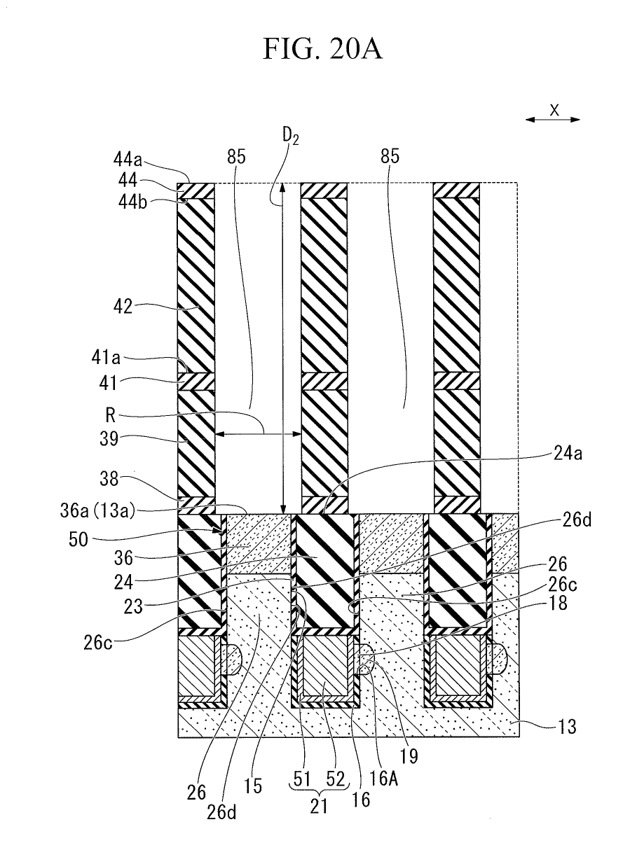

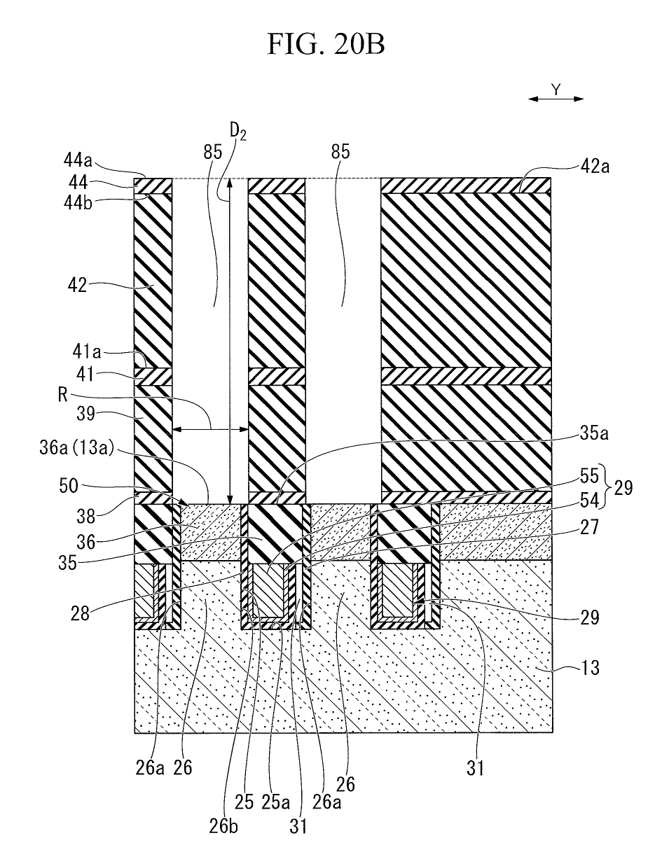

The first etching stopper film 38 functions as an etching stopper film, when cylinder holes 85 (see FIGS. 20A and 20B) are perforated through the second etching stopper film 41, the inter-layer insulation films 39 and 42, and the support film 44 by anisotropic etching (specifically, dry etching).

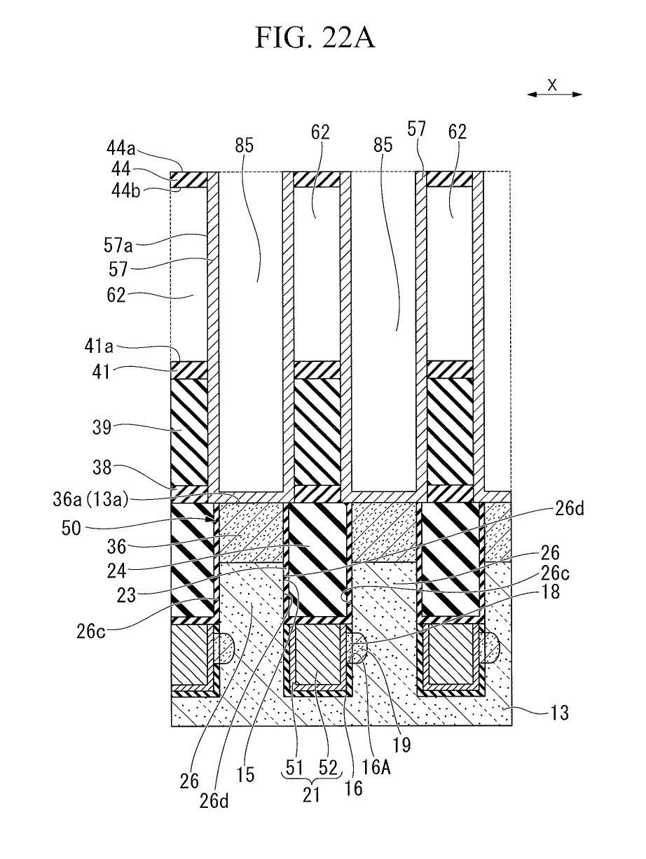

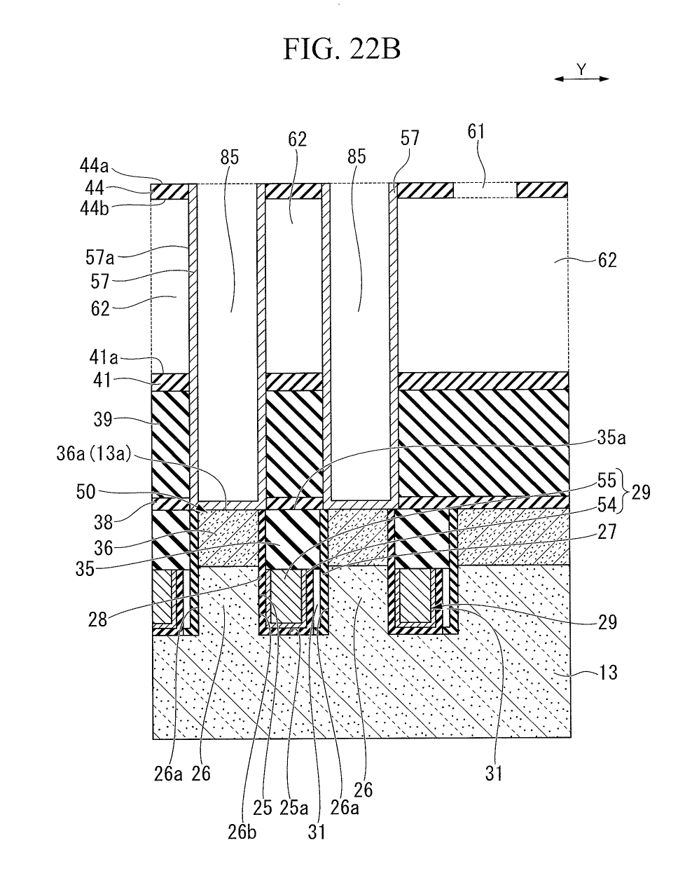

The second etching stopper film 41 function as preventing the structure disposed in the lower layers of the second etching stopper film 41 from being etched when the inter-layer insulation film 42 in which the memory cell region is formed is removed by wet etching in the steps described later in FIGS. 22A and 22B. That is, the second etching stopper film 41 functions as a stopper film in the wet etching.

Further, the second etching stopper film 41 has a function of connecting the plurality of lower electrodes 57 to each other when the inter-layer insulation film 42 in which the memory cell region is formed is removed in the steps described later in FIGS. 22A and 22B by connecting the lower portions of the plurality of lower electrodes 57.

In this step, the through portion 61 described above with reference to FIG. 2B has not yet been formed in the support film 44. That is, the support film 44 shown in FIGS. 19A and 19B is a silicon nitride film (SiN film) which is not patterned.

Next, in the steps shown in FIGS. 20A and 20B, the cylinder holes 85 exposing the upper surface 36a of the upper impurity diffusion region 36 are formed by etching the support film 44, the inter-layer insulation film 42, the second etching stopper film 41, the inter-layer insulation film 39, and the first etching stopper film 38 by anisotropic etching (specifically, dry etching).

Specifically, a photoresist (not shown), which has openings (not shown) exposing the upper surface 44a of the support film 44 corresponding to the regions where the cylinder holes 85 are formed, is formed on the upper surface 44a of the support film 44 shown in FIGS. 19A and 19B by a photolithography technique.

Subsequently, as a first step, first holes (not shown) perforating through the support film 44, the inter-layer insulation film 39, and the second etching stopper film 41 and having bottom surfaces located between the second etching stopper film 41 and the first etching stopper film 38 are formed by subjecting the inter-layer insulation films 39 and 42, the support film 44, and the second etching stopper film 41 to dry etching under the condition in which the support film 44 and the second etching stopper film 41 formed of the silicon nitride film (SiN film) are etched similarly with the inter-layer insulation films 39 and 42 formed of the silicon oxide film (SiO₂ film). The first hole is a hole which is a part of the cylinder hole 85.

Subsequently, as a second step, the inter-layer insulation film 39 is subjected to dry etching under the condition (in other words, a condition in which there is selectivity with respect to the silicon nitride film (SiN film)), in which the inter-layer insulation film 39 formed of the silicon oxide film (SiO₂ film) can selectively be etched, until the upper surface of the first etching stopper film 38 is exposed.

Thus, the regions where the first holes (not shown) are formed and second holes (not shown) are formed so as to be located below the first holes and have a depth deeper than that of the first hole.

Subsequently, as a third step, the first etching stopper film 38 is subjected to dry etching under the condition, in which the first etching stopper film 38 formed of the silicon nitride film (SiN film) is selectively etched, until the upper surface 36a of the upper impurity diffusion region 36 is exposed.

Thus, the regions where the second holes (not shown) are formed and the cylinder holes 85 are formed so as to be located below the second holes and having a depth deeper than that of the second hole.

The cylinder hole 85 is a hole in which the lower electrode 57 is formed. The cylinder hole 85 is formed so that the upper surface 36a of the upper impurity diffusion region 36 is exposed. Thereafter, the photoresist (not shown) is removed.

A diameter R of the cylinder hole 85 can be set to, for example, 60 nm, when the thickness of the first etching stopper 38 is 50 nm, the thickness of the inter-layer insulation film 39 is 400 nm, the thickness of the second etching stopper film 41 is 50 nm, the thickness of the inter-layer insulation film 42 is 900 nm, and the thickness of the support film 44 is 100 nm. In this case, a depth D₂ of the cylinder hole 85 can be set to 1500 nm.

When the cylinder hole 85 is formed, a guard wall groove (not shown) with a ring shape surrounding the memory cell region is formed. The guard wall groove is perforated through at least the support film 44, the inter-layer insulation film 42, and the second etching stopper film 41.

Next, in the steps shown in FIGS. 21A and 21B, the lower electrode 57 is formed by a CVD method so as to cover the inner surface (including the upper surface 36a of the upper impurity diffusion region 36 forming the bottom surface of the cylinder hole 85) of the cylinder hole 85.

Specifically, a Ti/TiN laminated film is formed by forming a titanium film (with a thickness of, for example, 10 nm) so as to cover the inner surface of the cylinder hole 85, and then forming a titanium nitride film (with a thickness of, for example, 20 nm) on the surface of the titanium film. Subsequently, the lower electrode 57 formed of the Ti/TiN laminated film is formed in each cylinder hole 85 by patterning the Ti/TiN laminated film by etching.

Further, in the steps shown in FIGS. 21A and 21B, a titanium film and a titanium nitride film are also formed in the inner surface of the guard wall groove (not shown), so that the titanium film and the titanium nitride film remain in the inner surface of the guard wall groove (not shown). The titanium film and the titanium nitride film formed in the guard wall groove (not shown) function as a guard wall (not shown).

The guard wall has a function of preventing the etchant from reaching the inter-layer insulation film 42 formed in the peripheral circuit region when the inter-layer insulation film 42 formed in the memory cell region is removed with an etchant in the steps described later in FIGS. 22A and 22B.

Subsequently, the support film 44 coming contact with the outer circumferential surfaces 57a of the upper ends of the plurality of lower electrodes 57 and connecting the plurality of lower electrodes 57 to each other is formed by forming the through portion 61, which exposes the upper surface 42a of the inter-layer insulation film 42 formed in the lower layer of the support film 44, in the support film 44.

Specifically, the through portion 61 is formed in a method described below. First, a photoresist (not shown) having openings (not shown) exposing the upper surface 44a of the support film 44 and corresponding to the regions where the through portions 61 are formed on the upper surface 44a of the support film 44 shown in FIGS. 20A and 20B by a photolithography technique.

Subsequently, the through portions 61 are formed by etching the support film 44 by anisotropic etching (specifically, dry etching) using the photoresist as a mask until the upper surface of the inter-layer insulation film 42 is exposed. Thereafter, the photoresist (not shown) is removed.

Only one through portion 61 is shown in FIGS. 21A and 21B. In effect, the plurality of through portions 61 are formed in the steps shown in FIGS. 21A and 21B.

Next, in the steps shown in FIGS. 22A and 22B, the inter-layer insulation film 42 surrounded by the guard wall (not shown) is selectively removed by supplying a wet etchant for selectively etching the inter-layer insulation film 42 to the inter-layer insulation film 42 formed in the memory cell region via the through portion 61. Thus, the space 62 is formed between the second etching stopper film 41 and the support film 44.

An etchant (in other words, an etchant having selectivity with respect to the second etching stopper film 41 and the support film 44) for selectively etching the silicon oxide film is sued as the wet etchant. Specifically, for example, hydrofluoric acid (HF) is used as the wet etchant.

The space 62 is formed so as to expose the upper surface 41a of the second etching stopper film 41, the lower surface 44b of the support film 44, the outer circumferential side surface 57a of each of the plurality of lower electrodes 57 located between the second etching stopper film 41 and the support film 44, and the inner wall (not shown) of the guard wall.

At this time, since the second etching stopper film 41 prevents the wet etchant from intruding into the lower layer of the memory cell region, there is no damage to the inter-layer insulation film 39, the formed transistor (for example, the vertical MOS transistor 50), and the like.

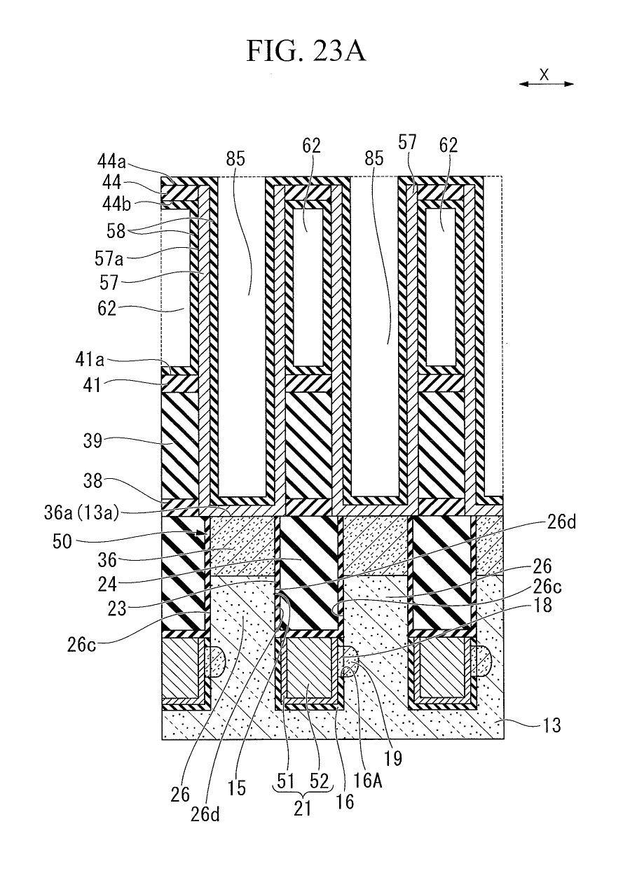

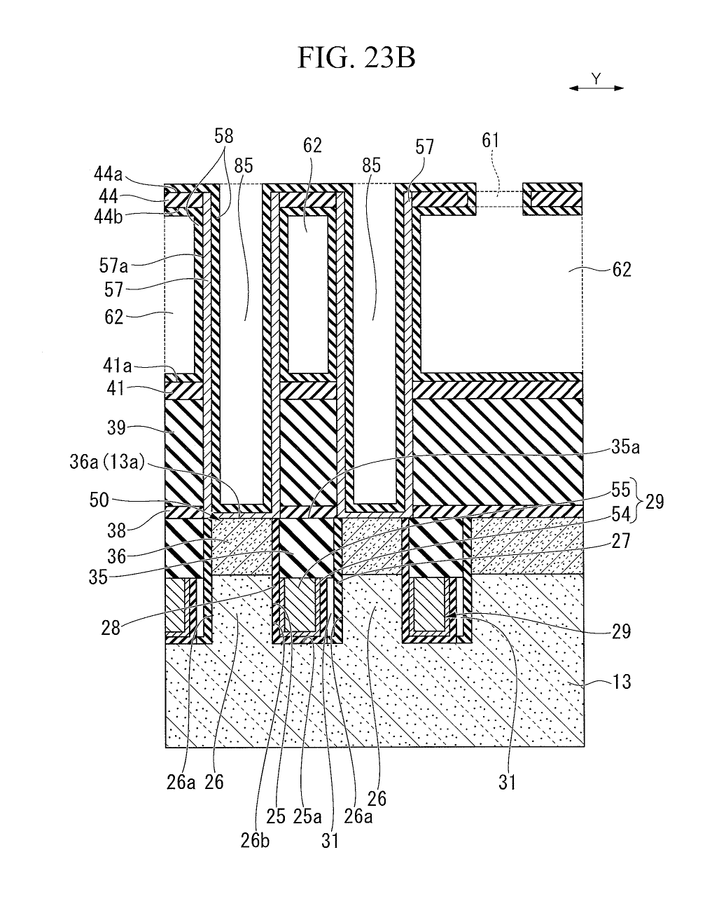

Next, in the steps shown in FIGS. 23A and 23B, the capacitive insulation film 58 covering a surface partitioning the space 62 is formed from the upper surface of the structure shown in FIGS. 22A and 22B via the through portion 61 by an ALD (Atomic Layer Deposition) method.

Thus, the capacitive insulation film 58 is formed so as to cover the upper surface 41a of the second etching stopper film 41, the upper surface 44a and the lower surface 44b of the support film 44, and the outer circumferential side surface 57a of each of the plurality of lower electrodes 57 located between the second etching stopper film 41 and the support film 44.

For example, a laminated film in which an aluminum oxide film (Al₂O₃ film) and a zirconium oxide film (ZrO₂ film) are laminated can be used as the capacitive insulation film 58.

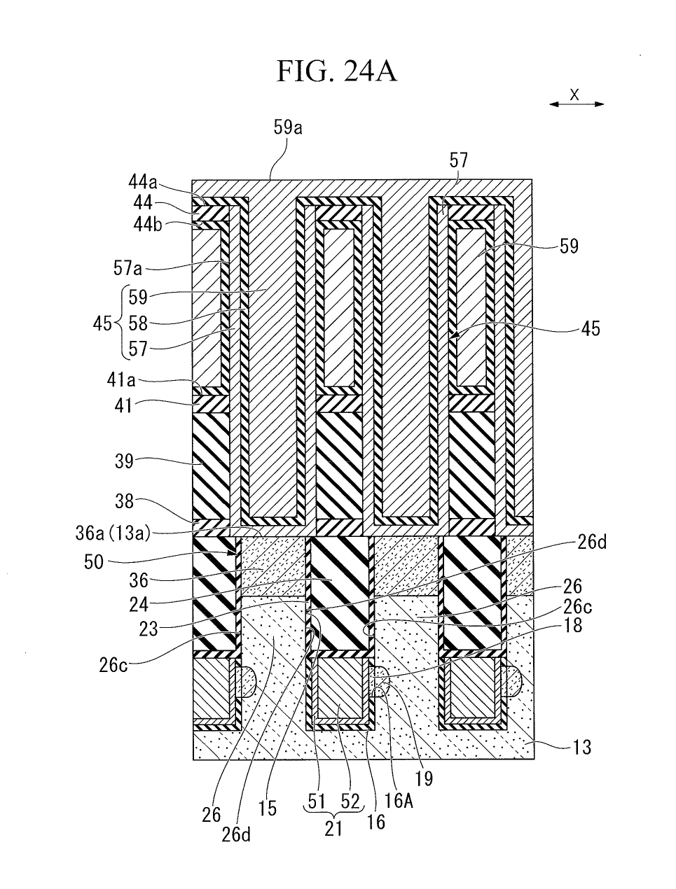

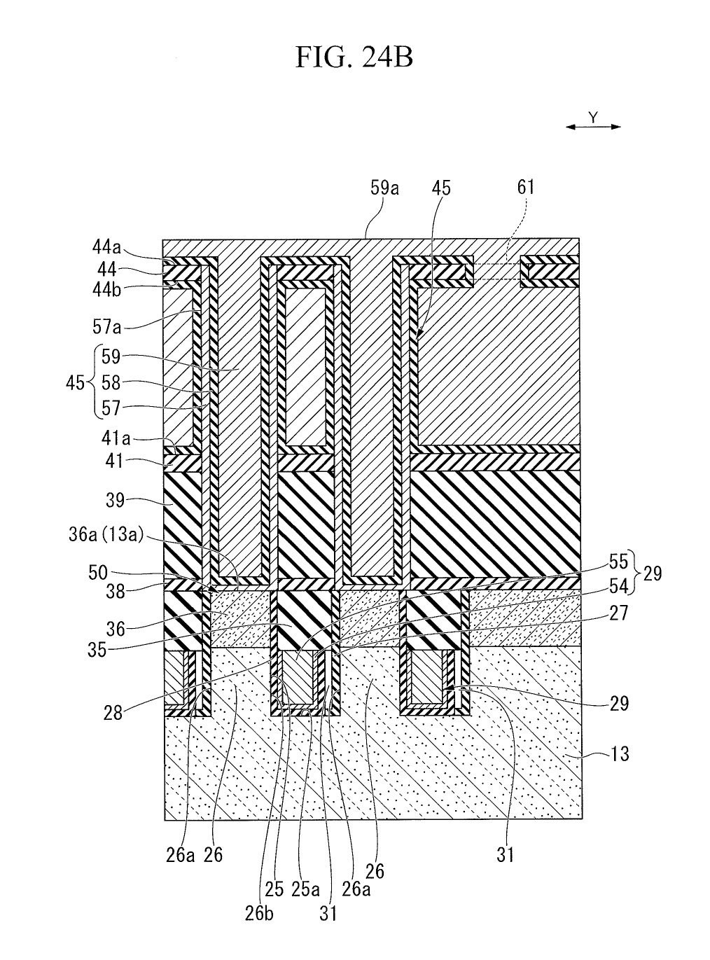

Next, in the steps shown in FIGS. 24A and 24B, a conductive film (not shown) covering the surface of the capacitive insulation film 58 and filling the space 62 is formed from the upper surface of the structure shown in FIGS. 23A and 23B via the through portion 61 by a CVD method. This conductive film is a base material of the upper electrode 59. For example, a metal film such as a ruthenium (Ru) film, a tungsten (W) film, or a titanium nitride (TiN) film or a polycrystalline silicon film can be used as the conductive film.

Subsequently, the upper electrode 59 formed of the conductive film and having the upper surface 59a configured to be flat is formed by polishing the conductive film by a CMP method.

Thus, the capacitor 45 (MIM capacitor), which includes the lower electrode 57, the capacitive insulation film 58, and the upper electrode 59 and comes into contact with the upper surface 36a of the upper impurity diffusion region 36, is formed above the upper impurity diffusion region 36.

Further, the capacitance of the capacitor 45 can be increased by forming the space 62, which exposes the upper surface 41a of the second etching stopper film 41, the lower surface 44b of the support film 44, and the outer circumferential side surface 57a of each of the plurality of lower electrodes 57, between the second etching stopper film 41 and the support film 44, forming the capacitive insulation film 58 covering the surface partitioning the space 62, and then forming the upper electrode 59 filling the space 62 on the surface of the capacitive insulation film 58.

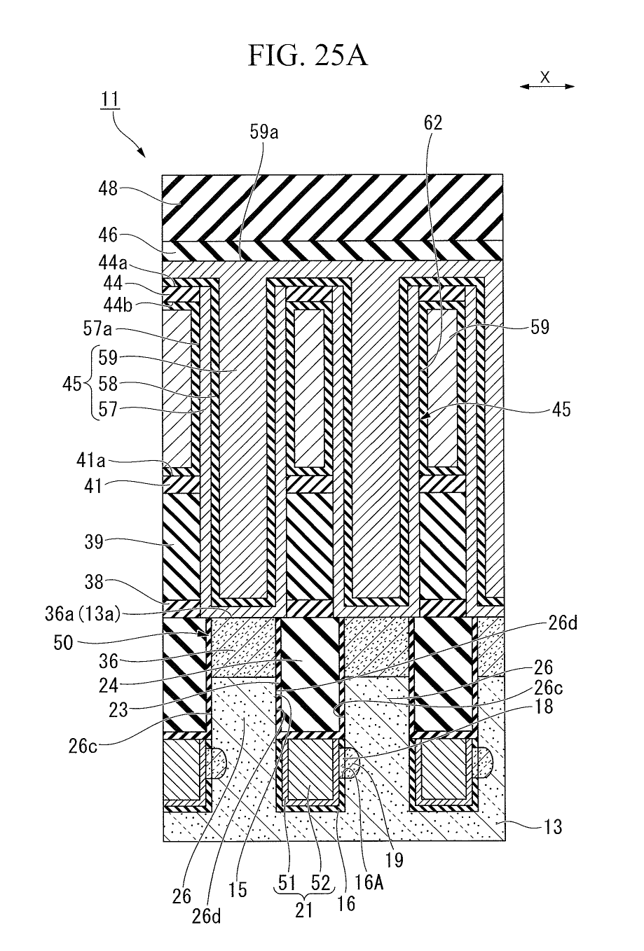

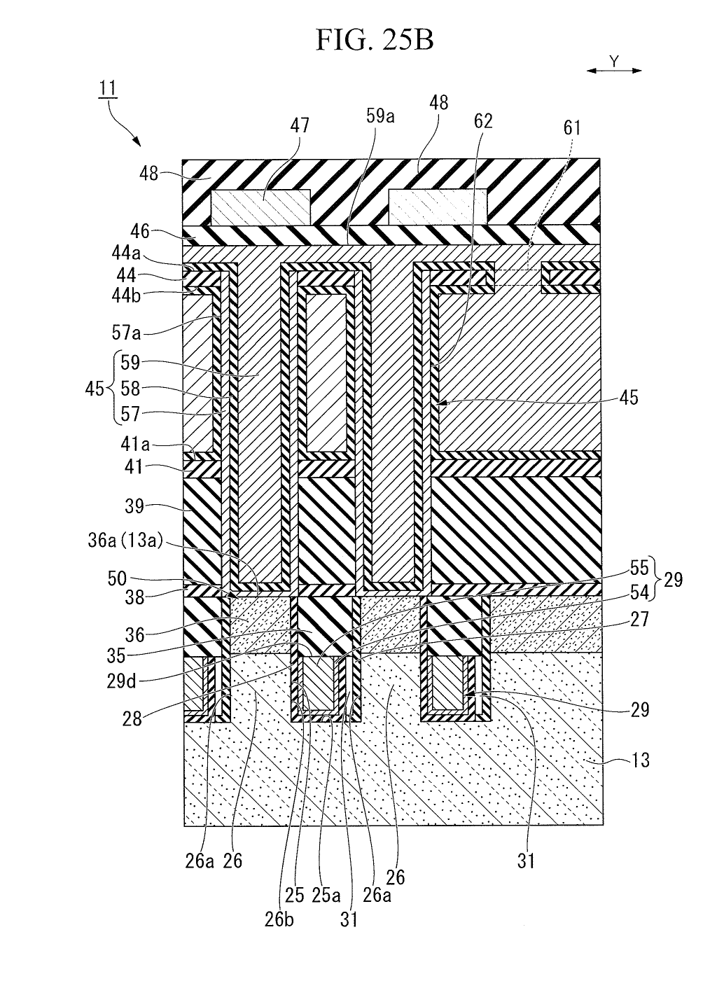

Next, in the steps shown in FIGS. 25A and 25B, the inter-layer insulation film 46 is formed on the upper surface 59a of the upper electrode 59. The inter-layer insulation film 46 can be formed by a CVD method. Further, a silicon oxide film (SiO₂ film) is used as the inter-layer insulation film 46.

Subsequently, the wiring 47 electrically connected to the upper electrode 59 is formed on the inter-layer insulation film 46 by a known method.

Subsequently, the inter-layer insulation film 48 is formed on the inter-layer insulation film 46 so as to cover the wiring 47. The inter-layer insulation film 48 can be formed by a CVD method. A silicon oxide film (SiO₂ film) is used as the inter-layer insulation film 48. In this way, the semiconductor device 10 according to the first embodiment is manufactured.

The method of manufacturing the semiconductor device according to the first embodiment includes forming the first insulation film 27, the first sidewall film 75-1, and the gate insulation film 28 in the second groove 25, forming the first conductive film 54 and the second conductive film 55 filling the second groove 25, etching back the entire surfaces of the first conducive film 54 and the second conductive film 55, and forming one gate electrode 29 formed by the first conducive film 54 and the second conductive film 55 in the lower portion 25A of the second groove 25. According to the method of manufacturing the semiconductor device, the width W₃ of the gate electrode 29 can be sufficiently ensured, thereby reducing the resistance value of the gate electrode 29, compared to a manufacturing method according to the related art in which dry etching is performed to divide a conductive film filling one groove into two films to form two gate electrodes.

In particular, when the pillar 26 is further miniaturized, the channel can be formed in the entire portion located between the upper impurity diffusion region 36 and the lower impurity diffusion region 19 in the pillar 26. Therefore, it is possible to obtain the same advantage as that of a gate electrode having a double gate structure in which one pillar is interposed between both sides.

Further, the pillar 26 is interposed between the gate electrodes 29 by forming the void 31 being in the vacuum state between the gate insulation film 28 formed on the side surface 29a of the gate electrode 29 and the first insulation film 27 formed on the first side surface 26a of the pillar 26. Thus, the capacitance between the gate electrodes 29 can be made to be small by the shield effect of the pillar 26.

Furthermore, the void 31 with the desired with W₂ can easily be formed by forming the void 31 formed between the gate insulation film 28 formed of the silicon oxide film (SiO₂ film) and the first insulation film 27 and formed by selectively removing the first sidewall film 75-1 forming the void 31 formed of the silicon nitride film (SiN film) by the wet etching.

### Second Embodiment

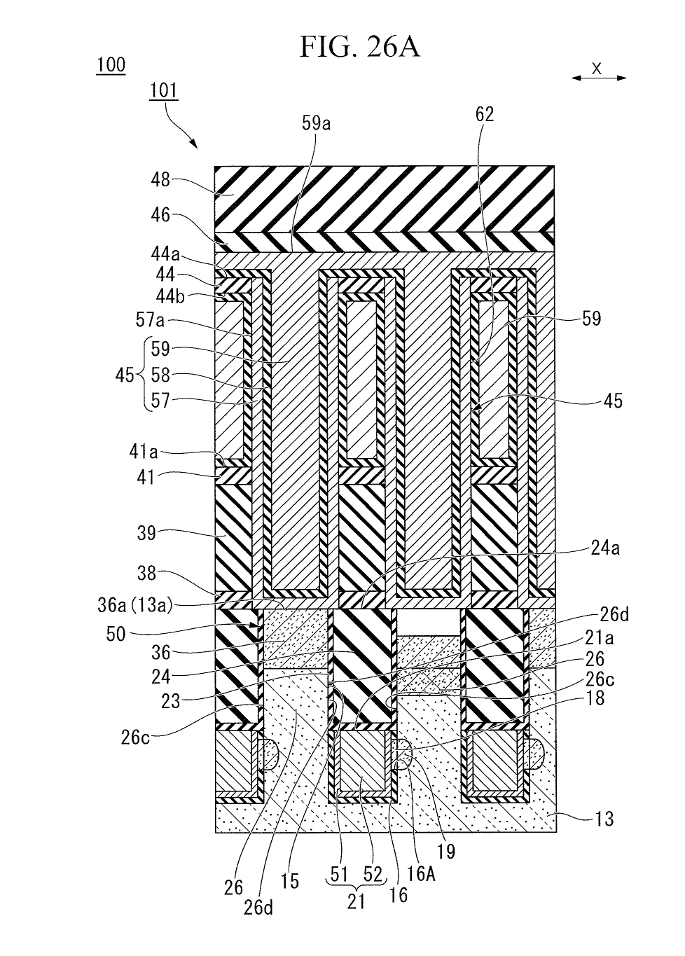

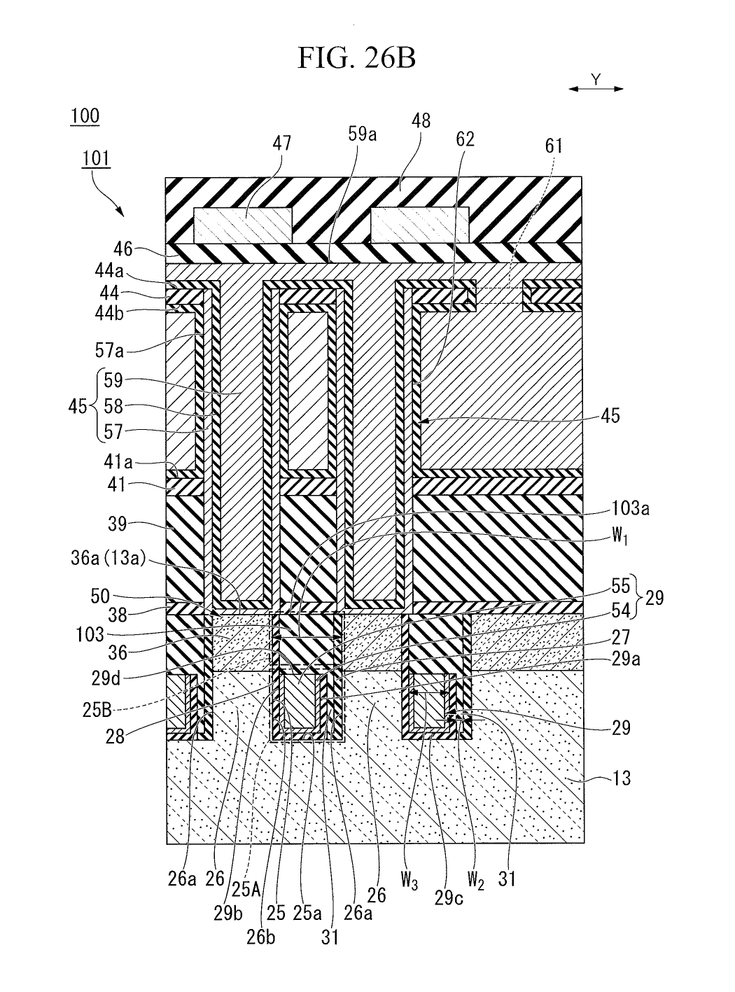

FIG. 26A is a sectional view schematically illustrating a memory cell array installed in a semiconductor device according to a second embodiment of the invention and is a sectional view taken along the line A-A of the memory cell array shown in FIG. 1. FIG. 26B is a sectional view schematically illustrating the memory cell array installed in the semiconductor device according to the second embodiment of the invention and is a sectional view taken along the line B-B of the memory cell array shown in FIG. 1.

In FIGS. 26A and 26B, the same reference numerals are given to the same constituent elements as those of the semiconductor device 10 (specifically, the memory cell array 11) according to the first embodiment shown in FIGS. 2A and 2B.

Referring to FIGS. 26A and 26B, a semiconductor device 100 according to the second embodiment has the same configuration as that of the semiconductor device 10 except that a buried insulation film 103 for a gate electrode is used instead of the buried insulation film 35 for a gate electrode of the memory cell array 11 installed in the semiconductor device 10 according to the first embodiment.

Referring to FIG. 26B, the buried insulation film 103 for a gate electrode has a burying characteristic more excellent than that of the buried insulation film 35 for a gate electrode described in the first embodiment. The buried insulation film 103 for a gate electrode is formed so as to fill the second groove 25 in which the first insulation film 27, the gate insulation film 28, and the gate electrode 29 are formed and includes the void 31.

That is, the buried insulation film 103 for a gate electrode is formed so as to fill the upper portion 25B of the second groove 25 and the void 31 formed in the lower portion 25A of the second groove 25.

For example, a silicon oxide film (SiO₂ film) formed by an LP-CVD method which has excellent burying characteristics can be used as the buried insulation film 103 for a gate electrode.

The semiconductor device 100 with the above-described configuration according to the second embodiment has the same advantages as those of the semiconductor device 10 according to the first embodiment.

Specifically, in the semiconductor device 100 according to the second embodiment, the resistance value of the gate electrode 29 can be reduced and the capacitance between the gate electrodes 29 can be reduced.

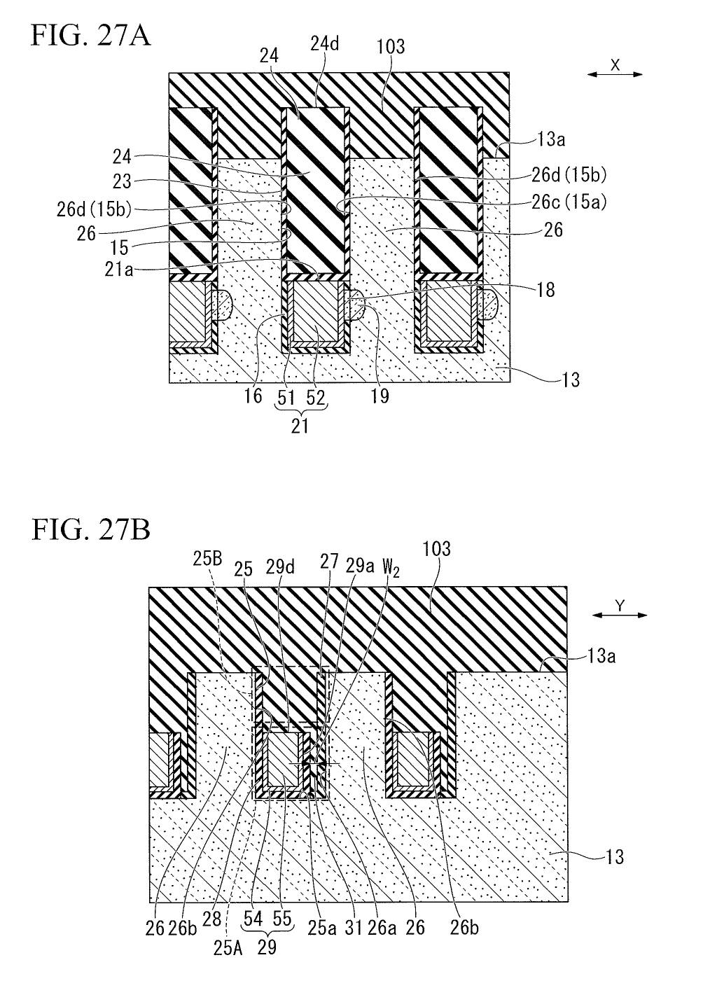

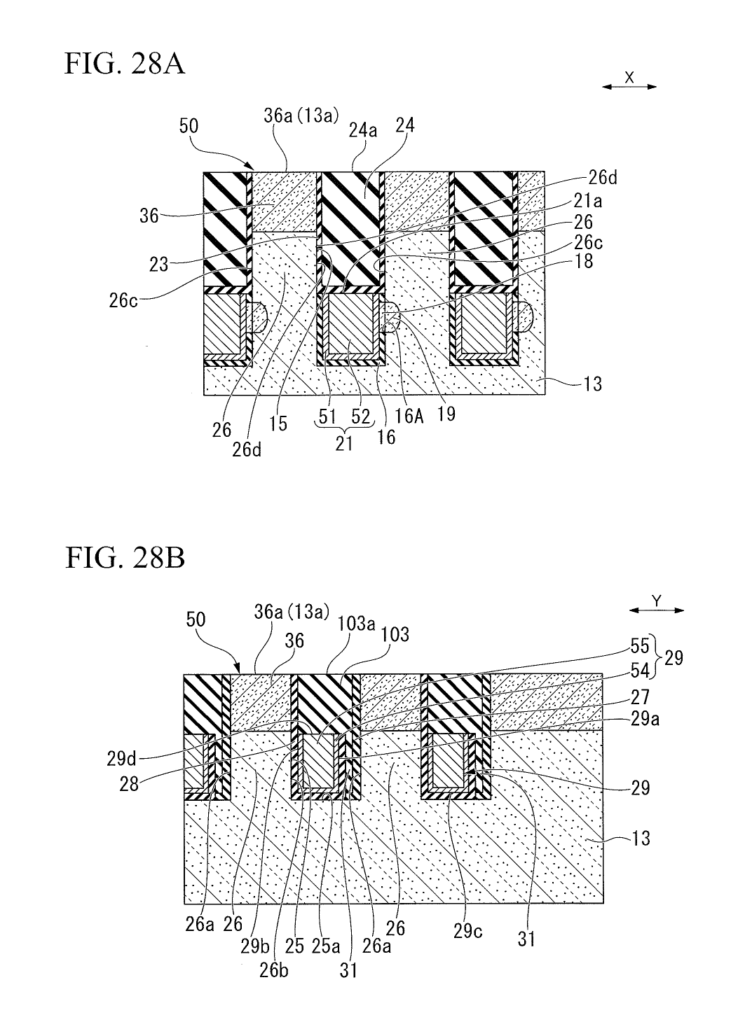

FIGS. 27A, 27B, 28A, and 28B are diagrams illustrating a method of manufacturing the memory cell array installed in the semiconductor device according to the second embodiment of the invention.

FIGS. 27A and 28A are sectional views illustrating a cut surface of memory cell array 101 shown in FIG. 26A. FIGS. 27B and 28B are sectional views illustrating a cut surface of the memory cell array 101 shown in FIG. 26B.

In FIGS. 27A, 27B, 28A, and 28B, the same reference numerals are given to the same constituent elements as those of the memory cell array 101 shown in FIGS. 26A and 26B.

Next, a method of manufacturing the memory cell array 101 installed in the semiconductor device 100 according to the second embodiment of the invention will be described with reference to FIGS. 27A, 27B, 28A, and 28B.

First, the structure shown in FIGS. 16A and 16B is formed by sequentially performing the steps described in the first embodiment with reference to FIGS. 3A and 3B to the steps described with reference to FIGS. 16A and 16B.

Next, in the steps shown in FIGS. 27A and 27B, the buried insulation film 103 for a gate electrode is formed so as to fill the second groove 25 in which the first insulation film 27, the gate insulation film 28, and the gate electrode 29 are formed and which includes the void 31.

Specifically, the upper portion 25B of the second groove 25 and the void 31 formed in the lower portion 25A of the second groove 25 are filled by forming a silicon oxide film (SiO₂ film) becoming the buried insulation film 103 for a gate electrode by an LP-CVD method.

Next, in the steps shown in FIGS. 28A and 28B, the main surface 13a of the semiconductor substrate 13 is exposed by removing the insulation film 23, the buried insulation film 24 for a bit line, and the buried insulation film 103 (in other words, unnecessary insulation films) formed above the main surface 13a (in other words, the upper surface of the pillar 26) of the semiconductor substrate 13 shown in FIGS. 27A and 27B by etching-back under the condition in which the silicon oxide film (SiO₂ film) can selectively be etched.

Thus, the upper end surface of the insulation film 23, the upper surface 24a of the buried insulation film 24 for a bit line, and the upper surface 103a of the buried insulation film 103 for a gate electrode are substantially flush with the main surface 13a of the semiconductor substrate 13.

Thereafter, the memory cell array 101 of the semiconductor device 100 according to the second embodiment shown in FIGS. 26A and 26B is manufactured by sequentially performing the processes of the steps described in the first embodiment with reference to FIGS. 19A and 19B to the steps described with reference to FIGS. 25A and 25B.

According to the method of manufacturing the semiconductor device 100 described in the second embodiment, it is possible to obtain the same advantages as those of the method of manufacturing the semiconductor device 10 according to the first embodiment.

The preferred embodiments of the invention have hitherto been described, but the invention is not limited to the specific embodiments. The invention may be modified in various forms within the scope of the invention described in claims departing from the gist of the invention.

The invention can be applied to a semiconductor device and a method of manufacturing the semiconductor device.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware and/or software that is constructed and/or programmed to carry out the desired function.

Furthermore, the particular features, structures, or characteristics may be combined in any suitable manner in one or more embodiments.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor substrate having a first groove and a first pillar defined by the first groove, the first groove and the first pillar being adjacent to each other; and
a first gate structure in the first groove, the first gate structure including a first gate insulating film and a first gate electrode, the first gate structure being separated by a first gap from the first pillar.

2. The semiconductor device according to claim 1, further comprising:
a buried insulating film over the first gate structure and the first gap, the buried insulating film burying an upper portion of the first groove,
wherein the first gate structure is disposed in a lower portion of the first groove.

3. The semiconductor device according to claim 1, wherein the semiconductor device further has a second groove extending in parallel to the first groove and in a first direction, and third and fourth grooves extending in a second direction crossing the first direction,
the first pillar is defined by the first, second, third and fourth grooves.

4. The semiconductor device according to claim 3, further comprising:
a second gate structure in the second groove, the second gate structure including a second gate insulating film and a second gate electrode, the second gate structure being adjacent to the first pillar.

5. The semiconductor device according to claim 1, further comprising:
a first upper diffusion region disposed in an upper portion of the first pillar; and
a first lower diffusion region disposed in a lower portion of the first pillar.

6. The semiconductor device according to claim 1, further comprising:
a first insulating film in the first groove, the first insulating film covering a first side surface of the first pillar, the first side surface of the first pillar facing toward the gate structure, the first insulating film being separated by the first gap from the gate structure.

7. The semiconductor device according to claim 1, wherein the first gap is surrounded by the first gate insulating film, the first insulating film and the first buried insulating film.

8. The semiconductor device according to claim 7, wherein the buried insulating film is lower in gap filling property than the first insulating film and the gate insulating film.

9. The semiconductor device according to claim 8, wherein the first gap is a vacuum gap.

10. The semiconductor device according to claim 6, wherein the first insulating film fills the first gap.

11. The semiconductor device according to claim 1, wherein the first gap is smaller in width than the gate structure, and a total width of the gate structure and the first gap is smaller than a width of the first groove.

12. The semiconductor device according to claim 3, wherein the third and fourth grooves have bottoms which are deeper than bottoms of the first and second grooves.

13. The semiconductor device according to claim 12, further comprising:
a first bit line in a lower portion of the third groove;
a second insulating film being disposed between the first pillar and the first bit line;
a first bit contact in the second insulating film, the first bit contact contacting the first bit line;
a first upper diffusion region disposed in an upper portion of the first pillar; and
a first lower diffusion region disposed in a lower portion of the first pillar, the first lower diffusion region being electrically coupled through the first bit contact to the first bit line.

14. The semiconductor device according to claim 12, further comprising:
a bit line burying insulating film in an upper portion of the third groove, the bit line burying insulating film covering the first bit line; and
a capacitor electrically coupled to the first upper diffusion region.

15. A semiconductor device comprising:
a semiconductor substrate having a first groove and a first pillar defined by the first groove, the first groove and the first pillar being adjacent to each other; and
a first gate structure in the first groove, the first gate structure including a first gate insulating film and a first gate electrode, the first gate structure being separated by a first empty space from the first pillar.

16. The semiconductor device according to claim 15, further comprising:
a buried insulating film over the first gate structure and the first empty space, the buried insulating film burying an upper portion of the first groove,
wherein the first gate structure is disposed in a lower portion of the first groove.

17. The semiconductor device according to claim 15, wherein the first empty space is a vacuum space.

18. A semiconductor device comprising:
a semiconductor substrate having first and second grooves extending in a first direction, and third and fourth grooves extending in a second direction crossing the first direction, and a first pillar defined by the first, second, third and fourth grooves;
a first gate structure in a lower portion of the first groove, the first gate structure including a first gate insulating film and a first gate electrode;
a first insulating film in the first groove, the first insulating film covering a first side surface of the first pillar, the first side surface of the first pillar facing toward the gate structure, the first insulating film being separated by the first gap from the gate structure, the first insulating film covering the first side surface of the first pillar being separated by a first gap from the first gate structure; and
a buried insulating film over the first gate structure and the first gap, the buried insulating film burying an upper portion of the first groove.

19. The semiconductor device according to claim 18, further comprising:
a first bit line in a lower portion of the third groove;
a second insulating film being disposed between the first pillar and the first bit line;
a first bit contact in the second insulating film, the first bit contact contacting the first bit line;
a first upper diffusion region disposed in an upper portion of the first pillar; and
a first lower diffusion region disposed in a lower portion of the first pillar, the first lower diffusion region being electrically coupled through the first bit contact to the first bit line.

20. The semiconductor device according to claim 19, further comprising:
a bit line burying insulating film in an upper portion of the third groove, the bit line burying insulating film covering the first bit line; and
a capacitor electrically coupled to the first upper diffusion region.
